(19) United States
(12) Patent Application Publication
(10) Pub. No.: US 2026/0082796 A1
(43) Pub. Date: Mar. 19, 2026

(54) RESIN COMPOSITION, METHOD OF MANUFACTURING DISPLAY DEVICE, DISPLAY DEVICE AND ELECTRONIC DEVICE

(71) Applicant: Samsung Display Co., Ltd., Yongin-si (KR)

(72) Inventor: Katsuhiro YAMAMOTO, Yokohama-shi (JP)

(21) Appl. No.: 19/324,683

(22) Filed: Sep. 10, 2025

(30) Foreign Application Priority Data
Sep. 13, 2024 (JP) 2024-158927

(51) Int. Cl. H10K 59/80; C09J 4/06; C09J 133/06; H10K 59/12

(52) U.S. Cl. CPC H10K 59/873; C09J 4/06; C09J 133/066; H10K 59/1201

(57) ABSTRACT

The present disclosure relates to a resin composition, a method of manufacturing a display device and an electronic device, and the resin composition according to an embodiment includes at least one (meth)acrylate monomer, at least one urethane acrylate oligomer, and at least one photoinitiator, wherein the resin composition includes, based on the total weight of the resin composition, about 5 wt % or more and about 10 wt % or less of 2-acryloyloxyethyl succinate, and about 5 wt % or more and about 10 wt % or less of 4-hydroxybutyl acrylate.

### CROSS-REFERENCE TO RELATED APPLICATION

The present application claims priority to and the benefit of Japanese Patent Application No. 2024-158927, filed on Sep. 13, 2024, in the Japanese Patent Office, the entire content of which is hereby incorporated by reference.

### BACKGROUND

### 1. Field

Embodiments of the present disclosure herein relate to a resin composition, a method of manufacturing a display device and an electronic device.

### 2. Description of the Related Art

Various display devices used in multimedia devices such as televisions, mobile phones, tablet computers, navigation systems and game consoles are being developed. Recently, in order to facilitate portability and improve user convenience, development of display devices that are equipped with flexible display members and are capable of folding, bending and/or rolling is being conducted.

In flexible display devices, each member used should secure reliability in folding and/or bending operations. An adhesive resin used to form an adhesive layer applied to display devices having various shapes should have excellent coating properties for members of display devices having various shapes.

### SUMMARY

An object of embodiments of the present disclosure is to provide a resin composition that exhibits excellent adhesiveness and reliability.

In embodiments, another object of the present disclosure is to provide a method of manufacturing a display device including an adhesive member formed of a resin composition.

In embodiments, another object of the present disclosure is to provide a display device including an adhesive member formed of a resin composition.

In embodiments, another object of the present disclosure is to provide an electronic device including an adhesive member formed of a resin composition.

An embodiment provides a resin composition including at least one (meth)acrylate monomer, at least one urethane acrylate oligomer, and at least one photoinitiator, wherein the resin composition includes based on a total weight of the resin composition, about 5 wt % or more and about 10 wt % or less of 2-acryloyloxyethyl succinate and about 5 wt % or more and about 10 wt % or less of 4-hydroxybutyl acrylate.

In an embodiment, the resin composition may have a viscosity at about 25° C. of about 15 mPa·s or more and about 25 mPa·s or less.

In an embodiment, the urethane acrylate oligomer may have a weight average molecular weight of about 10,000 or more and about 38,000 or less.

In an embodiment, the resin composition may further include one or more kinds of (meth)acrylate monomers different from the 4-hydroxybutyl acrylate.

In an embodiment, the resin composition may further include at least one selected from among 2-ethylhexyl acrylate, tetrahydrofurfuryl acrylate, and 2-ethylhexyl diglycol acrylate.

In an embodiment, the resin composition may have a storage elastic modulus at about 25° C. after photocuring of about 0.01 MPa or more and about 0.1 MPa or less.

An embodiment provides a method of manufacturing a display device, the method including providing a resin composition on a first plate and forming an adhesive member from the resin composition, wherein the resin composition includes at least one (meth)acrylate monomer, at least one urethane acrylate oligomer, and at least one photoinitiator, and based on the total weight of the resin composition, about 5 wt % or more and about 10 wt % or less of 2-acryloyloxyethyl succinate and about 5 wt % or more and about 10 wt % or less of 4-hydroxybutyl acrylate.

In an embodiment, a first area and a second area around (e.g., surrounding) the first area may be defined in the first plate, and in the providing of the resin composition, the resin composition may be provided in the first area with a constant (e.g., substantially constant) thickness and in the second area having a height difference in a thickness direction.

In an embodiment, a thickness of the resin composition applied to the first area may be smaller than the maximum thickness of the resin composition applied to the second area.

In an embodiment, the resin composition applied to the second area may include a peak part having the maximum thickness from the upper surface of the first plate.

In an embodiment, a horizontal distance from an edge of the first plate to which the resin composition is applied to the peak part may be about 300 μm or more and about 500 μm or less.

In an embodiment, the resin composition may be provided by an inkjet printing method.

An embodiment provides an electronic device including a display device and a control part to control the display device, wherein the display device including a display panel, a window on the display panel, and an adhesive member including a polymer derived from the resin composition and between the display panel and the window.

In an embodiment, the adhesive member may have a storage elastic modulus at about 25° C. of about 0.01 MPa or more and about 0.1 MPa or less.

In an embodiment, the adhesive member may have a 180° peel strength of about 500 gf/25 mm or more for at least one selected from among a glass substrate and a polymer substrate at a temperature of about 25° C.

In an embodiment, the electronic device may be a television, a monitor, an outdoor billboard, a personal computer, a laptop computer, a personal digital assistant, a vehicle display device, a game console, a smartwatch, and/or a camera.

### BRIEF DESCRIPTION OF THE DRAWINGS

The accompanying drawings are included to provide a further understanding of the subject matter of the present disclosure and are incorporated in and constitute a part of this specification. The drawings illustrate embodiments of the present disclosure and, together with the description, serve to explain principles of the present disclosure. In the drawings:

FIG. 1 is a block diagram of an electronic device according to an embodiment;

FIG. 2 is a schematic diagram of electronic devices according to embodiments;

FIG. 3 is a perspective view of a display device according to an embodiment of the present disclosure;

FIG. 4 is a diagram illustrating a folding state of the display device illustrated in FIG. 3;

FIG. 5 is a perspective view of a display device according to an embodiment of the present disclosure;

FIG. 6 is a diagram illustrating a folding state of the display device illustrated in FIG. 5;

FIG. 7 is a perspective view of a display device according to an embodiment of the present disclosure;

FIG. 8 is an exploded perspective view of a display device according to an embodiment of the present disclosure;

FIG. 9 is a cross-sectional view of a display device according to an embodiment of the present disclosure;

FIG. 10 is a cross-sectional view of a display device according to an embodiment of the present disclosure;

FIG. 11 is a cross-sectional view of a display device according to an embodiment of the present disclosure;

FIGS. 12A to 12D are diagrams schematically illustrating a method of manufacturing a display device according to an embodiment;

FIGS. 13A to 13E are drawings schematically showing a method of manufacturing a display device according to an embodiment; and

FIG. 14 is a cross-sectional view showing an enlarged view of area AA′ in FIG. 13C.

### DETAILED DESCRIPTION

The subject matter of the present disclosure may have various suitable modifications and may be embodied in different forms, and example embodiments will be explained in more detail with reference to the accompanying drawings. The subject matter of the present disclosure may, however, be embodied in different forms and should not be construed as limited to the embodiments set forth herein. Rather, all modifications, equivalents, and substituents which are included in the spirit and technical scope of the present disclosure should be included in the present disclosure.

In this specification, it will be understood that if (e.g., when) an element (or a region, a layer, a portion, or the like) is referred to as being “on”, “connected to” or “coupled to” another element, it may be directly on, connected to, or coupled to the other element, or other elements may be therebetween.

In the description, “directly on” may mean that there is no additional layer, film, area and/or plate between a part such as a layer, film, area and another part. For example, “directly on” may mean that two layers or two members are provided without using an additional member such as an adhesive member therebetween.

Like reference numerals or symbols refer to like elements throughout. In the drawings, the thickness, ratio, and size of the elements may be exaggerated to effectively describe the technical contents of the present disclosure.

As used herein, the term “and/or” includes any and all combinations of one or more of the associated listed elements.

It will be understood that, although the terms “first”, “second”, and/or the like may be used herein to describe various elements, the elements are not to be limited by these terms. These terms are only used to distinguish one element from another element. For instance, a first element could be termed a second element without departing from the scope of the present disclosure. Similarly, a second element could be termed a first element. In this specification, the singular expressions “a”, “an” and “the” are intended to include the plural forms as well, unless the context clearly indicates otherwise.

In embodiments, the terms “below”, “under”, “on the lower side”, “above”, “over”, “on the upper side”, and/or the like may be used to describe the relationships between the elements illustrated in the drawings. These terms are relative concepts and are described on the basis of the directions indicated in the drawings. In this specification, “on” may refer to being placed on top of, as well as below, one of the members.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be further understood that the terms “comprises, includes, has” and/or “comprising, including, having”, if (e.g., when) used in this specification, specify the presence of stated features, numbers, steps, operations, elements, components or combinations thereof, but do not preclude the possibility of the presence or addition of one or more other features, numbers, steps, operations, elements, components, and/or combinations thereof.

Hereinafter, embodiments of the present disclosure will be described with reference to the drawings.

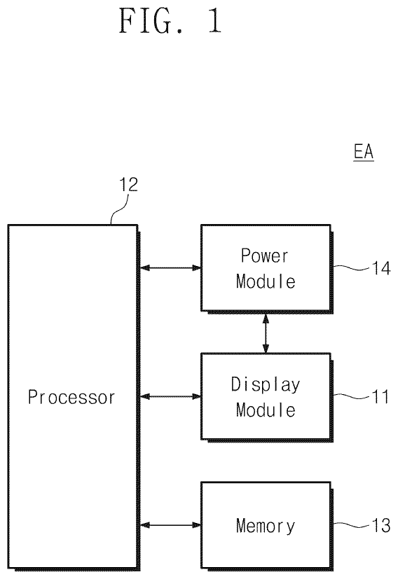

FIG. 1 is a block diagram of an electronic device according to an embodiment. Referring to FIG. 1, an electronic device EA according to an embodiment may include a display module 11, a processor 12, a memory 13, and a power module 14.

The processor 12 may include at least one of a central processing unit CPU, an application processor (AP), a graphic processing unit (GPU), a communication processor (CP), an image signal processor (ISP), or a controller.

The memory 13 may store data information necessary or useful to operate the processor 12 or the display module 11. If (e.g., when) the processor 12 executes an application stored in the memory 13, an image data signal and/or an input control signal is transmitted to the display module 11, and the display module 11 may process the provided signal and output image information through a display screen. The display module 11 may include a display panel that displays an image.

The power module 14 may include a power supply module such as a power adapter and/or a battery device, and a power conversion module that converts power supplied by the power supply module to generate power required or useful to operate the electronic device EA.

At least one of the elements of the electronic device EA described above may be included in a display panel according to embodiments described below and a display device of an embodiment including the same. In embodiments, some of the individual modules functionally included in one module may be included in the display device and other parts may be provided separately from the display device. For example, the display device may include the display module 11, and the processor 12, the memory 13, and the power module 14 may be provided in the form of other devices within the electronic device EA other than the display device. The processor 12, the memory 13, and the power module 14 may be included in the electronic device EA as a control part that controls the display device.

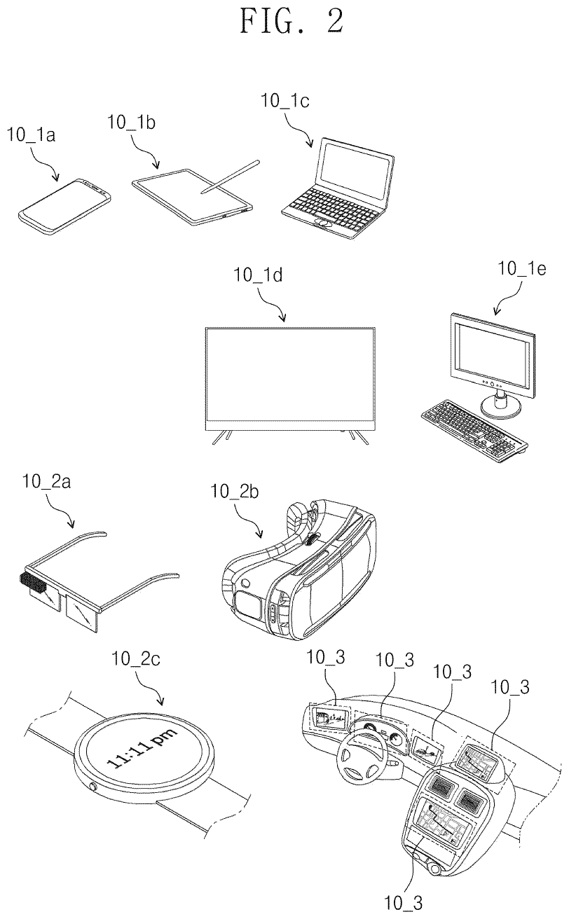

FIG. 2 illustrates a schematic diagram of electronic devices according to various suitable embodiments.

Referring to FIG. 2, various suitable electronic devices including a display device according to an embodiment may include not only electronic devices to display images, such as, for example, a smart phone 10_1a, a tablet PC 10_1b, a laptop 10_1c, a TV 10_1d, and/or a desk monitor 10_1e, but also wearable electronic devices, such as, for example, smart glasses 10_2a, a head-mounted display 10_2b, and/or a smart watch 10_2c, and/or vehicle electronic devices 10_3, such as, for example, the instrument panel, center fascia, a Center Information Display (CID) placed on a dashboard, and/or a room mirror display of a car.

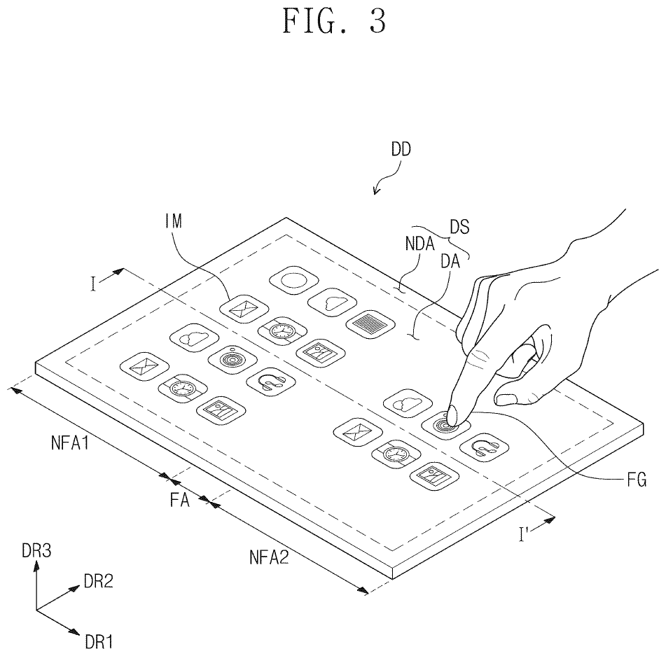

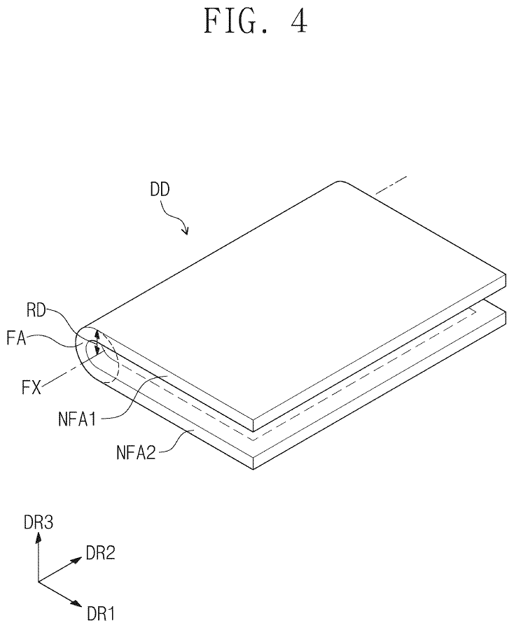

FIG. 3 is a perspective view of a display device according to an embodiment. FIG. 4 is a diagram illustrating a folding state of the display device illustrated in FIG. 3.

The display device DD of an embodiment illustrated in FIG. 3 may be a device activated according to an electrical signal. The display device DD of an embodiment may be included in the electronic device EA described above. The display device DD may be a part of the electronic device EA, which provides an image. For example, the electronic device EA may be a large-sized electronic device such as, for example, a television, a monitor, and/or an external billboard, as well as small and/or medium-sized electronic devices such as a personal computer, a notebook computer, a personal digital terminal, a vehicle display device such as, for example, a car navigation unit, a game console, a smart phone, a tablet, a smart watch, and/or a camera. These are presented only as illustrations, and the display device according to an embodiment may be employed in other electronic devices as long as it does not deviate from the spirit and scope of the present disclosure. The display device DD may be a flexible display device that may be folded, bent, and/or rolled.

Referring to FIG. 3, the display device DD of an embodiment may have a rectangular shape having long sides that extend in a first direction DR1 and short sides that extend in a second direction DR2 that intersects the first direction DR1. However, an embodiment of the present disclosure is not limited thereto, and the display device DD may have various suitable shapes such as, for example, a circle and/or a polygon on a plane.

The display device DD may display an image IM through a display surface DS. The display surface DS may include a display area DA and a non-display area NDA. The display area DA may be an area activated according to an electrical signal. The display device DD may display an image IM through the display area DA. The display area DA may detect various suitable types or kinds of external inputs. The non-display area NDA may be adjacent to the display area DA. The non-display area NDA may not display an image. The non-display area NDA may be around (e.g., surround) the display area DA. Accordingly, the shape of the display area DA may be substantially defined by the non-display area NDA. However, this is an illustration, and the non-display area NDA may be provided adjacent to only one side of the display area DA or may be omitted.

The display surface DS may be parallel (e.g., substantially parallel) to a plane defined by the first direction DR1 and the second direction DR2. The normal direction of the display surface DS, for example, the thickness direction of the display device DD, is indicated by a third direction DR3. The front (or upper surface) and the back (or lower surface) of each member are distinguished by the third direction DR3. However, the directions indicated by the first to third directions DR1, DR2 and DR3 are relative concepts and may be converted into other directions.

In this specification, “on a plane” may mean viewed on a plane parallel (e.g., substantially parallel) to the plane defined by the first direction DR1 and the second direction DR2. In this specification, “overlapping” may mean overlapping on a plane unless otherwise specifically defined.

The display device DD of an embodiment may detect an external input applied from the outside. The external input may include various suitable types or kinds of inputs such as force, pressure, temperature, and/or light. The display device DD may detect a user's touch input FG applied from the outside. In FIG. 1, and/or the like, the external input is illustrated as the user's hand applied to the display surface DS, but this is an illustration, and the user's touch input FG may be provided in various suitable forms. The user's touch input FG may include various suitable types or kinds of external inputs such as a part of the user's body, light, heat, and/or pressure. In embodiments, the display device DD may detect a user's input applied to the side and/or back of the display device DD depending on the structure, and is not limited to any one embodiment.

The display device DD of an embodiment may include at least one first folding area FA. Referring to FIGS. 3 and 4, the display device DD may include a first folding area FA and a plurality of non-folding areas NFA1 and NFA2. The first folding area FA may be between the non-folding areas NFA1 and NFA2. For example, the first folding area FA may be between the first non-folding area NFA1 and the second non-folding area NFA2. The first non-folding area NFA1 and the second non-folding area NFA2 may be spaced apart in the first direction DR1 with the first folding area FA interposed therebetween.

In FIGS. 3 and 4, one first folding area FA and two non-folding areas NFA1 and NFA2 are illustrated, but the number of the first folding area FA and the non-folding areas NFA1 and NFA2 is not limited thereto. The display device DD may include a plurality of folding areas. In embodiments, the display device DD may be folded based on a plurality of folding axes so that a portion of the display surface DS faces the display surface DS. The number of folding axes included in the display device DD and the number of non-folding areas according to the folding axes are not limited to any one embodiment.

Referring to FIG. 4, the display device DD may be folded based on the first folding axis FX. The first folding axis FX is an imaginary axis that extend in the second direction DR2 and may be parallel (e.g., substantially parallel) to the short side direction of the display device DD. However, this is an illustration, and the extension direction of the first folding axis FX is not limited to the second direction DR2. The extension direction of the first folding axis FX may be the first direction DR1. The folding area FA may be a portion that may be transformed into a folded form based on the first folding axis FX. The radius of curvature RD of the first folding area FA may be about 5 mm or less.

Referring to FIG. 4, the display device DD may be in-folded so that the first non-folding area NFA1 and the second non-folding area NFA2 face each other, so that the display surface DS (FIG. 3) is not exposed to the outside. However, an embodiment of the present disclosure is not limited thereto, and unlike as illustrated in FIG. 2, the display device DD may be out-folded so that the display surface DS is exposed to the outside.

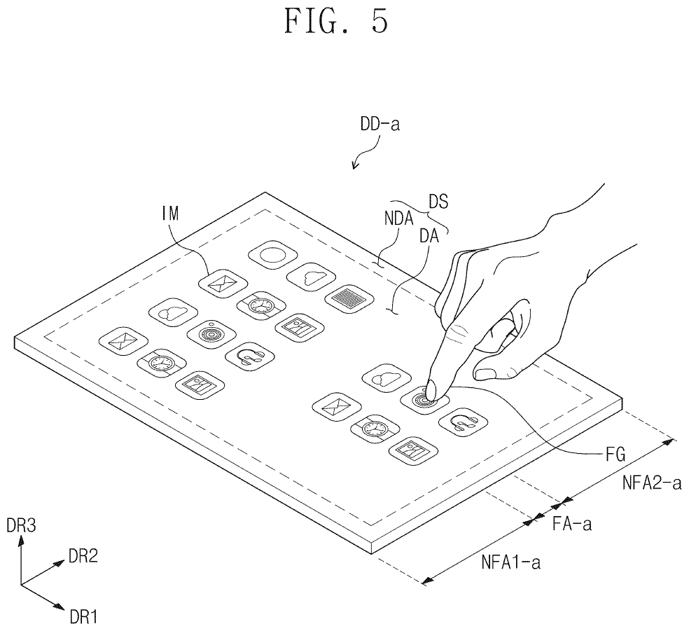

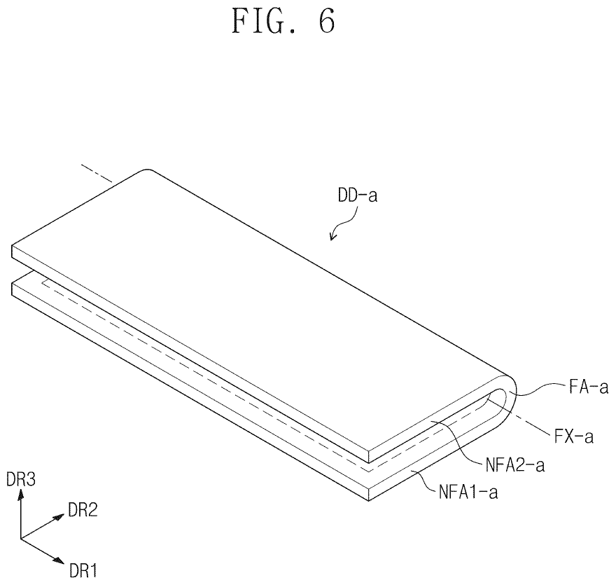

FIG. 5 is a perspective view of a display device DD-a according to an embodiment. FIG. 6 is a diagram illustrating a folding state of the display device DD-a illustrated in FIG. 5. The display device DD-a of FIG. 5 is different from the display device DD of FIG. 3 in the extension direction of the folding axis. The display device DD illustrated in FIG. 3 may be folded based on the short axis, and in contrast, the display device DD-a illustrated in FIG. 5 may be folded based on the long axis. The display device DD-a of FIG. 5 may include substantially the same elements as the display device DD of FIG. 3 except for the extension direction of the folding axis and accordingly, the folding operation. In describing the display device DD-a of FIGS. 5 and 6, any content overlapping with that described with reference to FIGS. 3 and 4 may not be repeated here.

Referring to FIGS. 5 and 6, the display device DD-a may include a folding area FA-a and a plurality of non-folding areas NFA1-a and NFA2-a. In the display device DD-a illustrated in FIGS. 5 and 6, the folding area FA-a may be referred to as a second folding area. The second folding area FA-a may be between the non-folding areas NFA1-a and NFA2-a. For example, the second folding area FA-a may be between the third non-folding area NFA1-a and the fourth non-folding area NFA2-a. The third non-folding area NFA1-a and the fourth non-folding area NFA2-a may be spaced apart in the second direction DR2 with the second folding area FA-a therebetween.

The display device DD-a of an embodiment may be folded based on the second folding axis FX-a. The second folding axis FX-a may be an imaginary axis extending in the first direction DR1. The second folding axis FX-a may be parallel (e.g., substantially parallel) to the longitudinal direction of the display device DD-a. In FIG. 6, the display device DD-a is illustrated as being in-folded so that the display surface DS is not exposed to the outside, but an embodiment of the present disclosure is not limited thereto, and the display device DD-a may be folded based on the long axis and may be out-folded.

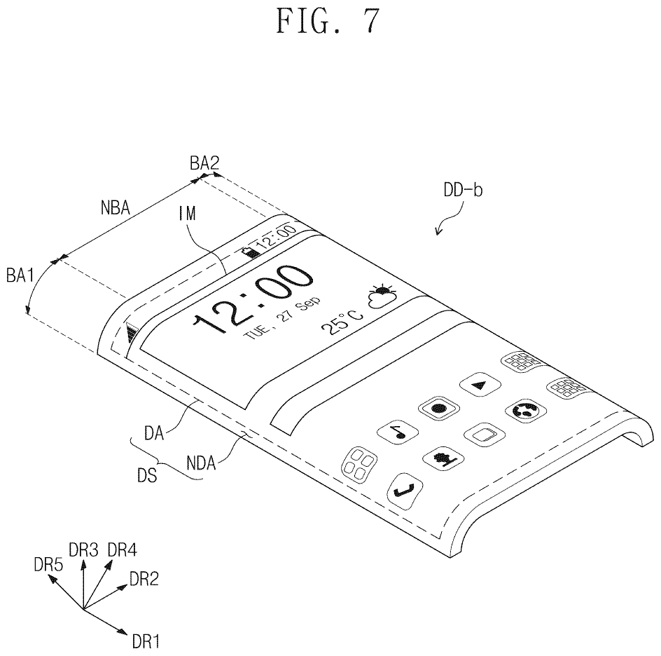

FIG. 7 is a perspective view of a display device DD-b according to an embodiment. The display device DD-b of an embodiment includes bending areas BA1 and BA2 and a non-bending area NBA, and the bending areas BA1 and BA2 may be bent from one side of the non-bending area NBA.

Referring to FIG. 7, the display device DD-b of an embodiment may include a non-bending area NBA in which an image IM is displayed in the front, a first bending area BA1 and a second bending area BA2, in which an image IM is displayed in the side. The first bending area BA1 and the second bending area BA2 may be bent from each side of the non-bending area NBA.

Referring to FIG. 7, the non-bending area NBA may provide an image IM in a third direction DR3 that is the front of the display device DD-b, and the first bending area BA1 may provide an image IM in a fifth direction DR5 and the second bending area BA2 may provide an image IM in a fourth direction DR4. The fourth direction DR4 and the fifth direction DR5 may be directions that intersect the first to third directions DR1, DR2 and DR3. However, the directions indicated by the first to fifth directions DR1 to DR5 are relative concepts and are not limited to the directional relationships illustrated in the drawings.

The display device DD-b of an embodiment may be a bending display device including a non-bending area NBA and bending areas BA1 and BA2 respectively on both sides of the non-bending area NBA. In some embodiments, the display device DD-b may be a bending display device including one non-bending area NBA and one bending area BA1 or BA2. The bending area BA1 or BA2 may be provided by being bent only at one side of the non-bending area NBA. For example, the display device DD-b may include a first bending area BA1 and a non-bending area NBA or a second bending area BA2 and a non-bending area NBA.

In FIGS. 3 to 7 above, a foldable display device and a bending display device are illustrated and described, but an embodiment of the present disclosure is not limited thereto. The display device of an embodiment may be a rollable display device, a flat rigid display device, and/or a curved rigid display device.

Hereinafter, the description of the display device of an embodiment is based on the display device DD that is folded based on a short axis, but an embodiment of the present disclosure is not limited thereto, and the contents described below may be applied not only to the display device DD-a that is folded based on a long axis and the display device DD-b that includes a bending area, but also to various suitable types or kinds of display devices.

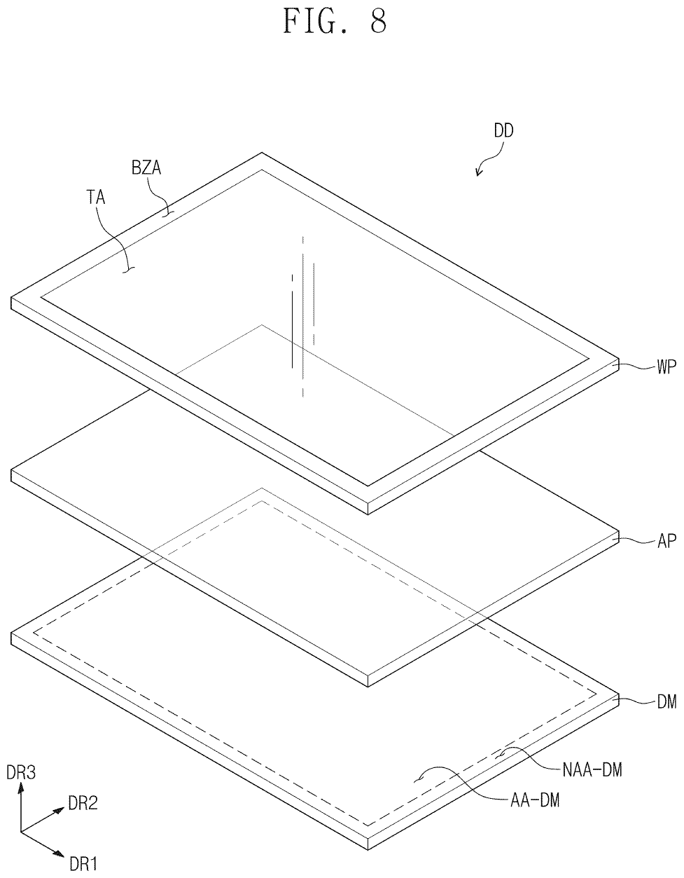

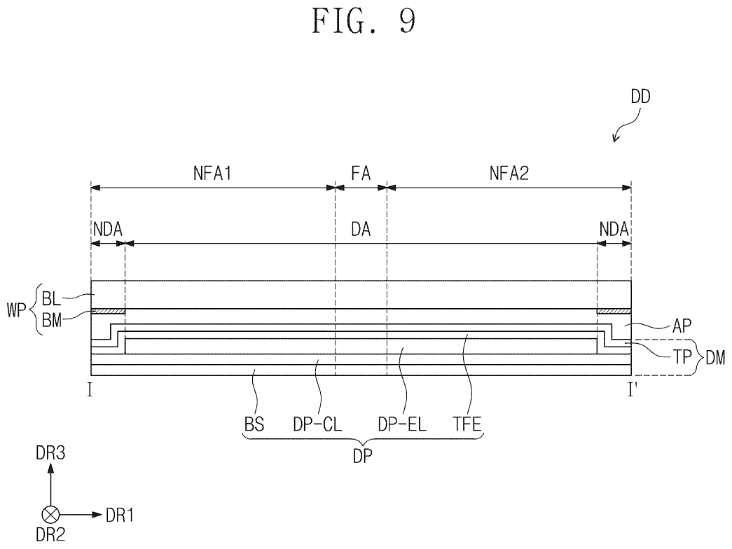

FIG. 8 is an exploded perspective view of a display device DD according to an embodiment. FIG. 9 is a cross-sectional view of a display device DD of an embodiment. FIG. 9 may be a cross-sectional view of a portion corresponding to line I-I′ in FIG. 3.

Referring to FIGS. 8 and 9, the display device DD of an embodiment may include a display module DM, a window WP on the display module DM, and an adhesive member AP between the display module DM and the window WP. The display module DM and the window WP may be coupled by the adhesive member AP. In some embodiments, the adhesive member AP may be between elements included in the display module DM.

The display module DM may be activated according to an electrical signal. The display module DM may be activated to display an image IM (FIG. 3) on a display area DA (FIG. 3) of the display device DD. An active area AA-DM and a peripheral area NAA-DM may be defined in the display module DM. The active area AA-DM may be an area activated according to an electrical signal. The peripheral area NAA-DM may be an area adjacent to at least one side of the active area AA-DM. Circuits and/or wiring to drive the active area AA-DM may be provided in the peripheral area NAA-DM. On a plane, the active area AA-DM may overlap with the display area DA (FIG. 3) and the peripheral area NAA-DM may overlap with the non-display area NDA (FIG. 3).

The display module DM may include a display panel DP and an input detection part TP on the display panel DP. The display panel DP may include a base substrate BS, a circuit layer DP-CL on the base substrate BS, a display element layer DP-EL on the circuit layer DP-CL, and an encapsulation layer TFE that covers the display element layer DP-EL. The configuration of the display panel DP illustrated in FIG. 9 is an illustration, and the configuration of the display panel DP is not limited to that illustrated in FIG. 9, or the like. For example, the display panel DP may include a liquid crystal display element, and in embodiments, the encapsulation layer TFE may be omitted.

The base substrate BS may provide a base surface on which the circuit layer DP-CL is provided. The base substrate BS may be a flexible substrate capable of bending, folding, rolling, and/or the like. The base substrate BS may be a glass substrate, a metal substrate, a polymer substrate, and/or the like. However, an embodiment of the present disclosure is not limited thereto, and the base substrate BS may include an inorganic layer, an organic layer, or a composite material layer (e.g., a composite material layer including an inorganic layer and an organic layer).

The circuit layer DP-CL may include an insulating layer (e.g., an electrically insulating layer), a semiconductor pattern, a conductive pattern (e.g., an electrically conductive pattern), and a signal line. For example, the circuit layer DP-CL may include a switching transistor and a driving transistor to drive a light emitting element of the display element layer DP-EL.

The display element layer DP-EL may include a light emitting element that emits light. For example, the display element may be an organic light emitting element, an inorganic light emitting element, an organic-inorganic light emitting element, a micro LED, a nano LED, a quantum dot light emitting element, an electrophoretic element, an electrowetting element, and/or the like.

The encapsulation layer TFE may be on the upper side of the display element layer DP-EL. The encapsulation layer TFE may protect the display element layer DP-EL from foreign substances such as moisture, oxygen, and/or dust particles. The encapsulation layer TFE may include at least one inorganic layer. In embodiments, the encapsulation layer TFE may include at least one organic layer and at least one inorganic layer. For example, the encapsulation layer TFE may include an inorganic layer, an organic layer, and an inorganic layer that are sequentially laminated.

The input detection part TP may be on the display panel DP. For example, the input detection part TP may be directly on the encapsulation layer TFE of the display panel DP. The input detection part TP may detect an external input, change the same into a set or predetermined input signal, and provide the input signal to the display panel DP. For example, in the display device DD of an embodiment, the input detection part TP may be a touch detection part that detects a user's touch input FG (FIG. 3). The input detection part TP may recognize a user's direct touch, a user's indirect touch, a direct touch of an object, and/or an indirect touch of an object.

The input detection part TP may detect at least one selected from the position of an externally applied touch and the intensity (pressure) of the touch. The input detection part TP in an embodiment of the present disclosure may have various suitable structures or be composed of various suitable materials, and is not limited to any one embodiment. The input detection part TP may include a plurality of detection electrodes to detect an external input. The detection electrodes may detect an external input in a capacitive manner. The display panel DP may receive an input signal from the input detection part TP and generate an image corresponding to the input signal.

Referring to FIGS. 8 and 9, the window WP may protect the display panel DP and the input detection part TP, and/or the like. The image IM (FIG. 3) generated in the display panel DP may pass through the window WP and be provided to the user. The window WP may provide a touch surface of the display device DD. In a display device DD including a first folding area FA, the window WP may be a flexible window.

The window WP may include a base layer BL and a printing layer BM. The window WP may include a transparent area TA and a bezel area BZA. The front surface of the window WP including the transparent area TA and the bezel area BZA may correspond to the front surface of the display device DD.

The transparent area TA may be an optically transparent area. The bezel area BZA may be an area having a relatively low light transmittance (e.g., a relatively low visible light transmittance) compared to the transparent area TA. The bezel area BZA may have a set or predetermined color. The bezel area BZA may be adjacent to the transparent area TA and may be around (e.g., surround) the transparent area TA. The bezel area BZA may define the shape of the transparent area TA. However, an embodiment of the present disclosure is not limited to what is illustrated, and the bezel area BZA may be adjacent to only one side of the transparent area TA, or a portion thereof may be omitted.

The base layer BL may be a glass and/or plastic substrate. For example, a tempered glass substrate may be used as the base layer BL. In embodiments, the base layer BL may be formed of a flexible polymer resin. For example, the base layer BL may include polyimide, polyacrylate, polymethylmethacrylate, polycarbonate, polyethylenenaphthalate, polyvinylidene chloride, polyvinylidene difluoride, polystyrene, an ethylene vinylalcohol copolymer, or a combination thereof. However, an embodiment of the present disclosure is not limited thereto, and any suitable general form and/or material generally used in the art as a base layer BL of a window WP may be used without limitation.

The printing layer BM may be on one side of the base layer BL. In an embodiment, the printing layer BM may be provided on the lower surface of the base layer BL adjacent to the display module DM. The printing layer BM may be provided at an edge area of the base layer BL. The printing layer BM may be an ink printing layer. In embodiments, the printing layer BM may be a layer formed by including a pigment and/or a dye. In the window WP, the bezel area BZA may be a portion where the printing layer BM is provided.

The window WP may further include at least one functional layer provided on the base layer BL. For example, the functional layer may be a hard coating layer, an anti-fingerprint coating layer, and/or the like, but an embodiment of the present disclosure is not limited thereto.

The adhesive member AP may be between the display module DM and the window WP. The adhesive member AP included in the display device DD of an embodiment may be formed by providing a liquid resin composition on one side of the window WP or one side of the display module DM and curing the provided liquid resin composition with ultraviolet light. In embodiments, the adhesive member AP may be provided by curing a liquid resin composition with ultraviolet light in a separate process to form an adhesive film-shaped adhesive member AP, laminating one side of the adhesive member AP in the cured state in the adhesive-film shape on one side of the window WP or one side of the display module DM, and attaching one side of the window WP or one side of the display module DM, that is not attached to the remaining side of the adhesive member AP.

The thickness of the adhesive member AP may be about 50 μm or more and about 500 μm or less. For example, the thickness of the adhesive member AP may be about 50 μm or more and about 200 μm or less, or about 50 μm or more and about 100 μm or less. However, this is an illustration, and the thickness of the adhesive member AP is not limited thereto.

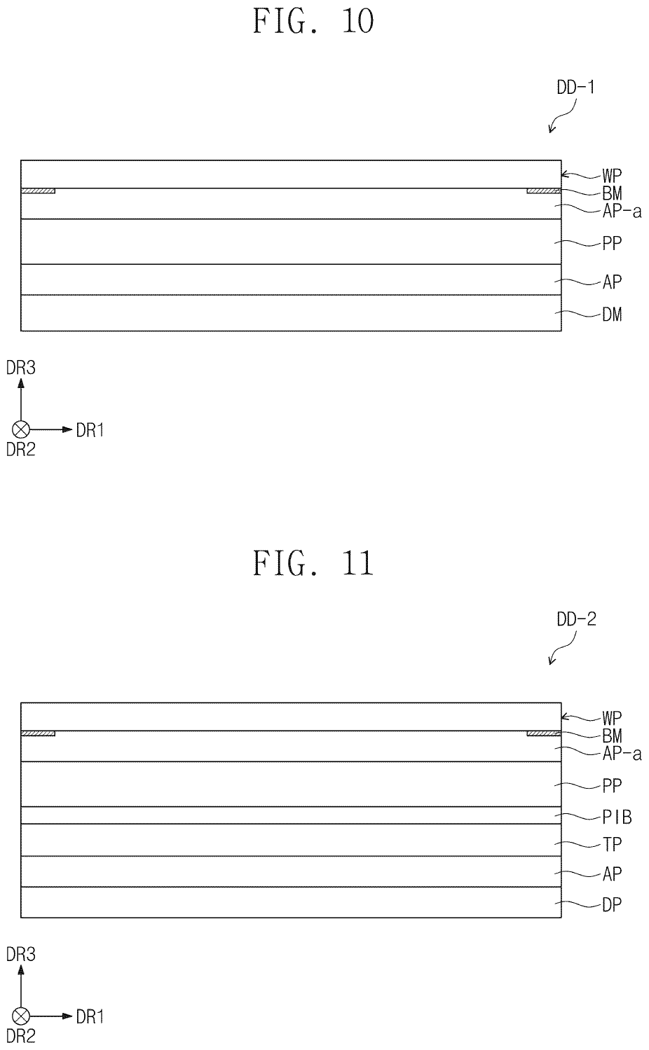

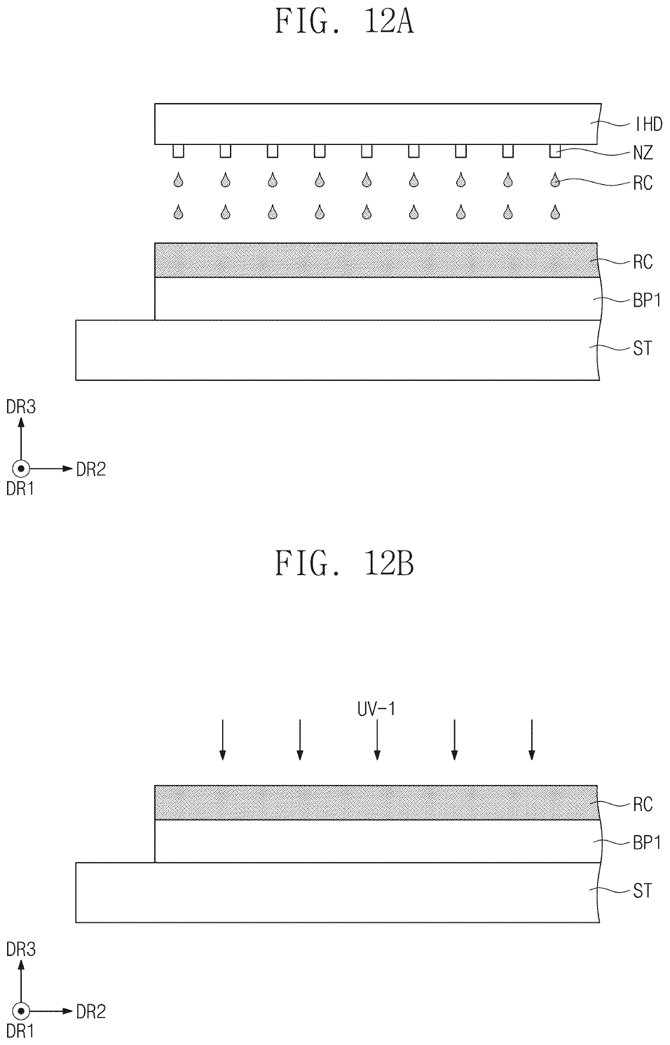

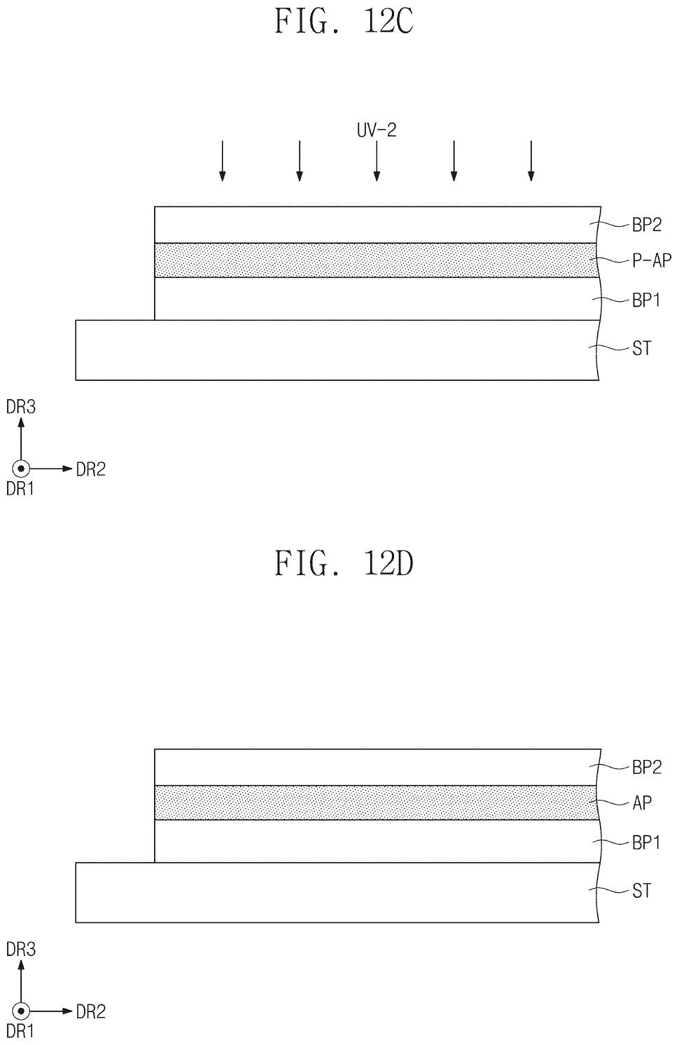

The adhesive member AP may be optically transparent. The adhesive member AP may be one of an optically clear adhesive resin (OCR) layer or an optically clear adhesive (OCA) film. The adhesive member AP may be an optically clear adhesive resin (OCR) layer. The adhesive member AP of an embodiment may include a polymer derived from a resin composition RC (FIG. 12A, and/or the like) of an embodiment described below. The adhesive member AP may be formed from the resin composition RC of an embodiment. The adhesive member AP formed from the resin composition RC of an embodiment may exhibit excellent adhesive reliability and elastic modulus. Accordingly, the display device DD including the adhesive member AP formed from the resin composition RC may thereby exhibit excellent durability in various suitable operating states such as folding, bending, and/or rolling.

The adhesive member AP of an embodiment may have an elastic modulus of about 0.01 MPa or more and about 0.1 MPa or less at a temperature of about 25° C. The elastic modulus may be a storage elastic modulus measured by a dynamic viscoelasticity measurement method in a shear (torsion) mode of about 1 Hz according to JIS K7244-7. The adhesive member AP may be formed from the resin composition RC (FIG. 12A, and/or the like) of an embodiment and has a storage elastic modulus of about 0.01 MPa or more and about 0.1 MPa or less at a temperature of about 25° C., so as to exhibit excellent impact resistance and excellent flexibility.

In embodiments, the adhesive member AP may have a 180° peel force of about 500 gf/50 mm or more for at least one selected from among a glass substrate and a polymer substrate at a temperature of about 25° C. For example, the adhesive member AP may have a 180° peel strength of about 500 gf/25 mm or more and about 1000 gf/25 mm or less for at least one selected from among a glass substrate and a polymer substrate at a temperature of about 25° C., but is not limited thereto. The polymer substrate may include polyethylene terephthalate (PET). The adhesive member AP is formed from a resin composition RC (FIG. 12A, and/or the like) of an embodiment and may exhibit excellent adhesion reliability because the 180° peel strength for at least one selected from among a glass substrate and a polymer substrate is about 500 gf/50 mm or more at a temperature of about 25° C.

FIG. 10 is a cross-sectional view showing a display device DD-1 according to an embodiment. In the description of the display device DD-1 of an embodiment illustrated in FIG. 10 below, any content overlapping with that described with reference to FIGS. 3 to 9 above may not be repeated here, and differences will be mainly described.

The display device DD-1 of an embodiment illustrated in FIG. 10 may further include a light control layer PP and an optical adhesive layer AP-a compared to the display device DD described with reference to FIGS. 8 and 9. The display device DD-1 of an embodiment may further include a light control layer PP between an adhesive member AP and a window WP, and an optical adhesive layer AP-a between the light control layer PP and the window WP.

The light control layer PP may be on a display panel DP to control light reflected from the display panel DP due to external light. The light control layer PP may include, for example, a polarizing layer and/or a color filter layer.

The optical adhesive layer AP-a may be an optically clear adhesive resin (OCR) layer and/or an optically clear adhesive (OCA) film. The optical adhesive layer AP-a may be formed from a resin composition RC (FIG. 12A, and/or the like) according to an embodiment. The optical adhesive layer AP-a may include a polymer derived from the resin composition RC according to an embodiment, similarly to the adhesive member AP. Accordingly, the optical adhesive layer AP-a including the polymer derived from the resin composition RC according to an embodiment has excellent adhesive strength and flexibility, so that a lifting phenomenon does not (or substantially does not) occur at the interface of the optical adhesive layer AP-a even if (e.g., when) the display device DD-1 is folded and/or bent, thereby exhibiting excellent adhesive reliability and folding characteristics.

A display device DD-1 of an embodiment may include an optical adhesive layer AP-a and an adhesive member AP including a polymer derived from a resin composition RC according to an embodiment, and a display device DD-1 including the optical adhesive layer AP-a and the adhesive member AP may exhibit excellent adhesive reliability during an operation such as folding.

FIG. 11 is a cross-sectional view showing a display device DD-2 according to an embodiment. In the description of the display device DD-2 of an embodiment illustrated in FIG. 11 below, any content overlapping with that described with reference to FIGS. 3 to 10 described above may not be repeated here, and differences will be mainly described.

The display device DD-2 of an embodiment illustrated in FIG. 11 may be such that, compared to the display device DD described with reference to FIGS. 8 and 9, an adhesive member AP is between members included in a display module DM. In embodiments, the display device DD-2 may further include a light control layer PP, an optical adhesive layer AP-a, and/or an interlayer adhesive layer PIB. The light control layer PP may be between the adhesive member AP and the window WP, and the optical adhesive layer AP-a may be between the light control layer PP and the window WP.

In the display device DD-2 of an embodiment, the adhesive member AP may be provided between the display panel DP and the input detection part TP. For example, the input detection part TP is not directly on the display panel DP, but the display panel DP and the input detection part TP may be coupled to each other by the adhesive member AP. For example, the adhesive member AP may be between the encapsulation layer TFE (FIG. 9) of the display panel DP and the input detection part TP.

An interlayer adhesive layer PIB may be provided on the lower side of the light control layer PP. The interlayer adhesive layer PIB may be between the input detection part TP and the light control layer PP and may be formed of an adhesive material having excellent moisture-proofing properties. For example, the interlayer adhesive layer PIB may be formed by including polyisobutylene. The interlayer adhesive layer PIB may be on the input detection part TP to prevent or reduce corrosion of the sensing electrodes of the input detection part TP.

The display device DD-2 of an embodiment may include an optical adhesive layer AP-a and an adhesive member AP including a polymer derived from a resin composition RC (FIG. 12A, and/or the like) according to an embodiment, and the display device DD-2 including the optical adhesive layer AP-a and the adhesive member AP may exhibit excellent reliability during an operation such as folding.

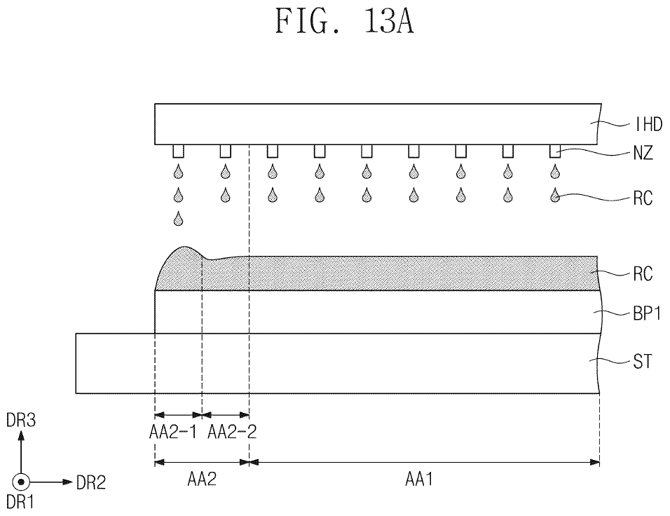

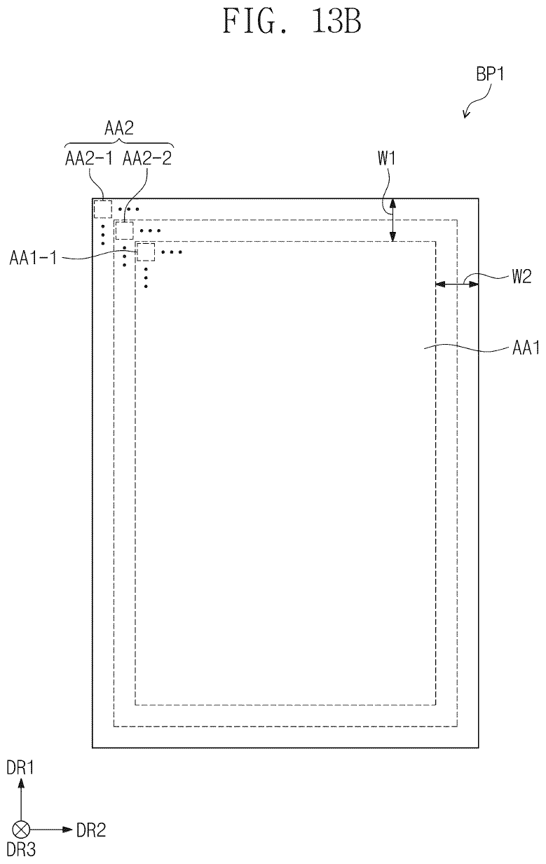

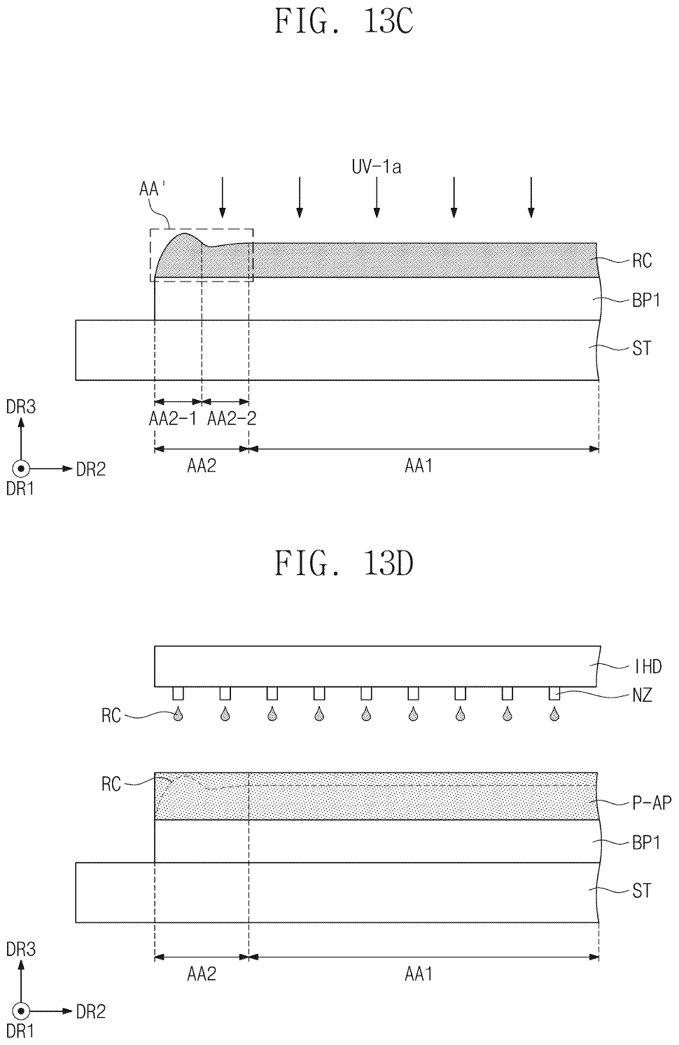

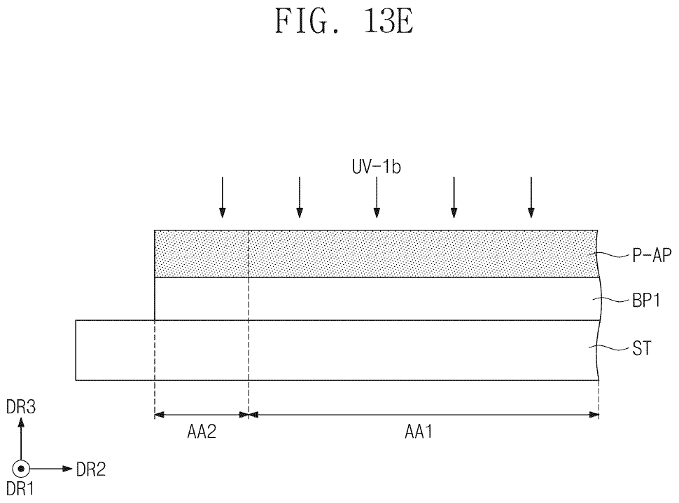

Hereinafter, a method of manufacturing a display device will be described with reference to FIGS. 12A to 12D and 13A to 13E. FIGS. 12A to 12D and 13A to 13E are diagrams schematically illustrating a method of manufacturing a display device according to an embodiment, respectively. The method of manufacturing a display device of an embodiment may include a method of forming an adhesive member from a resin composition of an embodiment. FIGS. 12A to 12D and 13A to 13E are diagrams schematically illustrating forming an adhesive member AP (see FIG. 9) in the method of manufacturing a display device. The adhesive member AP formed by the method described with reference to FIGS. 12A to 13E may be applied to the display devices DD, DD-a, DD-b, DD-1, and DD-2 described with reference to FIGS. 3 to 11. In the following description of a method of manufacturing a display device according to an embodiment, any overlapping content with the description of the display device according to the above-described embodiment may not be repeated here, and differences will be mainly described.

Referring to FIGS. 12A to 12D, a method of manufacturing a display device according to an embodiment may include providing a resin composition RC and forming an adhesive member AP. The adhesive member AP may be formed from the resin composition RC according to an embodiment. The forming the adhesive member AP may include curing the resin composition RC. The curing may include a first curing and a second curing.

Referring to FIG. 12A, the method of manufacturing a display device according to an embodiment may include preparing a first plate BP1 and providing a resin composition RC on the first plate BP1. The first plate BP1 may be placed on a stage ST to provide a reference surface on which the resin composition RC is provided. For example, the first plate BP1 may be a display module DM or a window WP described in FIG. 7. The resin composition RC may be directly provided on one surface of the first plate BP1.

The first plate BP1 may also be a temporary substrate used to form an adhesive member AP from the resin composition RC. If (e.g., when) the first plate BP1 is provided as a temporary substrate, the first plate BP1 may be used without limitation as long as the cured resin composition RC provided on the first plate BP1 may be easily detached after the resin composition RC is cured. For example, the first plate BP1 may include polyethylene terephthalate (PET). The first plate BP1 may be a PET film. If (e.g., when) the first plate BP1 is used as a temporary substrate, one surface of the first plate BP1 on which the resin composition RC is provided may be subjected to a release treatment. Accordingly, the cured resin composition RC may be easily detached from the first plate BP1.

In an embodiment, the resin composition RC may be provided on the first plate BP1 by an inkjet printing method and/or a dispensing method. The resin composition RC may be provided by an inkjet printing method and/or a dispensing method and may exhibit easy application properties to various suitably shaped members.

In an embodiment, the resin composition RC may be provided on the first plate BP1 by an inkjet printing method. The resin composition RC may be discharged from an inkjet head IHD on the upper side of the stage ST and provided on the first plate BP1. The inkjet head IHD includes a plurality of nozzles NZ and may be spaced apart from the upper surface of the stage ST by a set or predetermined distance. The nozzles NZ may be spaced apart from each other by a set or predetermined distance along one direction. For example, the nozzles NZ may be provided in a row along the second direction DR2, but an embodiment of the present disclosure is not limited thereto. The nozzles NZ may also be provided in a row along the first direction DR1. In embodiments, the nozzles NZ may be provided in two or more rows.

Each of the nozzles NZ may discharge the resin composition RC toward the first plate BP1. For example, the discharge direction of each of the nozzles NZ may be perpendicular (e.g., substantially perpendicular) to the first plate BP1. However, an embodiment of the present disclosure is not limited thereto. Each of the nozzles NZ may include a discharge port having a circular hole shape. However, an embodiment of the present disclosure is not limited thereto, and the shape of the discharge port of each of the nozzles NZ may be variously, suitably changed. In embodiments, the number and size of the nozzles NZ included in the inkjet head IHD may be variously, suitably changed.

A plurality of nozzles NZ included in the inkjet head IHD may be independently controlled by a control part. The amount of the resin composition RC discharged from each of the nozzles NZ may be controlled through the control part. Accordingly, the amount of the resin composition RC applied on the first plate BP1 may be adjusted to apply the resin composition RC in a suitable or desired shape. In embodiments, the inkjet head IHD may further include a storage part that stores the resin composition RC to be provided to the first plate BP1.

The resin composition RC of an embodiment may be a photocurable resin composition. The resin composition RC of an embodiment may be a UV-curable resin that is cured by ultraviolet light. The resin composition RC of an embodiment is a liquid phase before curing, and may be crosslinked and/or cured by receiving light energy such as ultraviolet light.

The resin composition RC of an embodiment may include 2-acryloyloxyethyl succinate and at least one (meth)acrylate monomer. At least one (meth)acrylate monomer may include 4-hydroxybutyl acrylate. In an embodiment, the (meth)acrylate monomer may include a (meth)acryloyl group. In embodiments of the present specification, the (meth)acryloyl group represents an acryloyl group or a methacryloyl group, and (meth)acryl represents acryl or methacryl. For example, the (meth)acrylate monomer may be an acrylate monomer or a methacrylate monomer containing one acryloyl group or one methacryloyl group.

The resin composition RC of an embodiment includes 2-acryloyloxyethyl succinate and 4-hydroxybutyl acrylate. In embodiments, the resin composition RC may further include one or more (meth)acrylate monomers other than 4-hydroxybutyl acrylate. In embodiments of this specification, 4-hydroxybutyl acrylate may be referred to as a first monomer, and a (meth)acrylate monomer different from 4-hydroxybutyl acrylate may be referred to as a second monomer. The resin composition RC of an embodiment includes the first monomer, and optionally may further include the second monomer. In embodiments, the resin composition RC may further include at least one selected from among a photoinitiator and a urethane acrylate oligomer.

The resin composition RC of an embodiment may not include a solvent. The resin composition RC may not include a volatile organic solvent. The resin composition RC may be provided in a solvent-free type (or kind of) resin composition RC. The solvent-free type resin composition RC may have improved ease of discharge from a coating device such as an inkjet head IHD. In embodiments, if (e.g., when) the solvent-free type resin composition RC is used in a process for manufacturing an adhesive member AP, unlike a resin composition containing a volatile organic solvent, a heating process for drying a volatile organic solvent, and/or the like may be omitted, thereby improving process efficiency.

The resin composition RC may be applied in any suitable or desired shape, and may have a suitable or appropriate viscosity that may be applied by an inkjet printing method, and/or the like. In an embodiment, the resin composition RC may have a viscosity of about 15 mPa·s or more and about 25 mPa·s or less. The viscosity of the resin composition RC may be a shear viscosity measured at a temperature of about 25° C. and about 10 rpm by the JIS Z8803 method. The resin composition RC has a viscosity of about 15 mPa·s or more and about 25 mPa·s or less at a temperature of about 25° C., so as to be easily discharged by an inkjet printing method and/or a dispensing method, and applied on the first plate BP1 in a shape set as a target.

If (e.g., when) the viscosity at a temperature of about 25° C. of the resin composition RC is less than about 15 mPa·s, flow occurs due to the relatively low viscosity, and thus the formation of a coating film of a uniform (e.g., substantially uniform) thickness with the resin composition RC or the application in a suitable or desired shape and thickness may be difficult. “Flow” refers to a phenomenon in which the resin composition RC flows out of a member to be provided. In embodiments, if (e.g., when) the viscosity of the resin composition RC exceeds about 25 mPa·s at a temperature of about 25° C., the discharge of a suitable or appropriate amount of the resin composition RC from a coating device used to apply the resin composition RC may be difficult.

In an embodiment, the resin composition RC may contain 2-acryloyloxyethyl succinate in an amount of about 5 wt % or more and about 10 wt % or less based on the total weight of the resin composition RC. For example, the resin composition RC may contain 2-acryloyloxyethyl succinate in an amount of about 5 wt % or more and about 10 wt % or less based on about 100 wt % of the total weight of the resin composition. If (e.g., when) the resin composition RC of an embodiment contains 2-acryloyloxyethyl succinate in the amount ranges described above, the resin composition RC may be easily applied to a coating object such as the first plate BP1 by an inkjet printing method, and may have a suitable or appropriate viscosity that allows application in a suitable or desired shape. If the content of 2-acryloyloxyethyl succinate included in the resin composition RC is deviated from the above-described ranges, the viscosity of the resin composition RC may be too high and thus application by an inkjet printing method may be unsuitable, or the viscosity of the resin composition RC may be too low and thus flow may occur.

The resin composition RC may contain 4-hydroxybutyl acrylate in an amount of about 5 wt % or more and about 10 wt % or less based on the total weight of the resin composition RC. For example, the resin composition RC may contain 4-hydroxybutyl acrylate in an amount of about 5 wt % or more and about 10 wt % or less based on about 100 wt % of the total weight of the resin composition. If (e.g., when) the resin composition RC of an embodiment contains 4-hydroxybutyl acrylate in the above-described amount ranges, the resin composition RC may be easily applied onto the first plate BP1 by an inkjet printing method, and may have a suitable or appropriate viscosity that may be applied in a suitable or desired shape. In embodiments, if (e.g., when) the resin composition RC contains 4-hydroxybutyl acrylate in the above-described amount ranges, the adhesive strength of the resin composition RC may be excellent. If (e.g., when) the amount of 4-hydroxybutyl acrylate included in the resin composition RC deviates from the above-described ranges, the viscosity of the resin composition RC may be excessively high or low, and the adhesive strength may be reduced.

The resin composition RC may include a second monomer. The second monomer may be a (meth)acrylate monomer of a different kind from 4-hydroxybutyl acrylate. The resin composition RC may further include one or two or more kinds of the second monomer. The second monomer may include at least one selected from among 2-ethylhexyl acrylate, tetrahydrofurfuryl acrylate, and 2-ethylhexyl diglycol acrylate. For example, the second monomer may include 2-ethylhexyl acrylate, tetrahydrofurfuryl acrylate, and 2-ethylhexyl diglycol acrylate. However, an embodiment of the present disclosure is not limited thereto.

If (e.g., when) the resin composition RC includes the second monomer, the resin composition RC may include the second monomer in an amount of about 50 wt % or more and about 80 wt % or less based on the total weight of the resin composition. For example, the resin composition RC may include the second monomer in an amount of about 50 wt % or more and about 80 wt % or less, or about 70 wt % or more and about 80 wt % or less based on 100 wt % of the total weight of the resin composition. If (e.g., when) the second monomer is included in the resin composition RC in the amount ranges described above, the adhesive member AP formed from the resin composition RC of an embodiment may exhibit improved peel strength and excellent elastic modulus. Therefore, the display device including the adhesive member AP of an embodiment may have excellent adhesive strength and may be easily folded and unfolded.

The resin composition RC of an embodiment may include at least one urethane acrylate oligomer. The resin composition RC may include one or two or more urethane acrylate oligomers. The weight average molecular weight of the urethane acrylate oligomer may be about 10,000 or more and about 38,000 or less. The urethane acrylate oligomer having a weight average molecular weight of about 10,000 or more and about 38,000 or less may be an oligomer state having a relatively high degree of polymerization. If (e.g., when) the urethane acrylate oligomer having the above-described weight average molecular weight is included in the resin composition RC, the resin composition RC may maintain a high degree of polymerization even after photocuring and may exhibit excellent flexibility. Therefore, the adhesive member AP formed from the resin composition RC of an embodiment may have both excellent adhesion and flexibility.

For example, the urethane acrylate oligomer may include at least one of UF-C051 (urethane acrylate, a product of Kyoeisha Chemical Co., Ltd.), UF-C052 (urethane acrylate, a product of Kyoeisha Chemical Co., Ltd.), or UN6304 (urethane acrylate, a product of Negami Chemical Industrial Co., Ltd.). However, this is an illustration, and the urethane acrylate oligomer included in the resin composition RC is not limited thereto.

If (e.g., when) the resin composition RC includes the urethane acrylate oligomer, the urethane acrylate oligomer may be included in an amount of about 1 wt % or more and about 15 wt % or less based on the total weight of the resin composition. For example, the resin composition RC may include about 1 wt % or more and about 15 wt % or less of the urethane acrylate oligomer based on 100 wt % of the total weight of the resin composition. However, this is an illustration, and the content of the urethane acrylate oligomer included in the resin composition RC is not limited thereto.

The resin composition RC of an embodiment may include at least one photoinitiator. The photoinitiator may include a radical polymerization initiator. The photoinitiator may be included in the resin composition in one or two or more types (or kinds). If (e.g., when) the resin composition includes a plurality of photoinitiators, each photoinitiator may be activated by ultraviolet light having a different center wavelength.

For example, the photoinitiator may include at least one selected from among 2,2-dimethoxy-1,2-diphenylethan-1-one, 1-hydroxy cyclohexyl-phenylketone, 2-hydroxy-2-methyl-1-phenyl-1-propanone, 2-hydroxy-1-[4-(2-hydroxyethoxy)phenyl]-2-methyl-1-propanone, and 2-hydroxy-1-{4-[4-(2-hydroxy-2-methyl-propionyl)-benzyl]-phenyl}-2-methylpropan-1-one.

In embodiments, the photoinitiator may include at least one selected from among 2-methyl-1-[4-(methylthio)phenyl]-2-morpholinopropan-1-one, 2-benzyl-2-dimethylamino-1-(4-morpholinophenyl)-butanone-1,2-dimethylamino-2-(4-methyl-benzyl)-1-(4-morpholin-4-yl-phenyl)-butan-1-one, 2,4,6-trimethylbenzoyl-diphenylphosphine oxide, ethyl(2,4,6-trimethylbenzoyl)phenyl phosphinate, phenylbis(2,4,6-trimethylbenzoyl) phosphine oxide, [1-(4-phenylsulfanylbenzoyl)heptylideneamino]benzoate, [1-[9-ethyl-6-(2-methylbenzoyl)carbazol-3-yl]ethylideneamino]acetate, and bis(2,4-cyclopentadienyl)bis[2,6-difluoro-3-(1-pyrryl)phenyl] titanium (IV). In embodiments, the resin composition RC may include at least one selected from among Omnirad 819 (IGM Resins) and Omnirad 184 (IGM Resins) as the photoinitiator. Omnirad 819 (IGM Resins) and Omnirad 184 (IGM Resins) are radical polymerization initiators.

Referring to FIG. 12B, the method of manufacturing a display device of an embodiment may include a first curing including providing a first light UV-1 to the resin composition RC applied to one surface of the first plate BP1. The first light UV-1 may be directly irradiated to the resin composition RC. The resin composition RC may be cured by the first light UV-1. The first light UV-1 may be ultraviolet light. The amount of the first light UV-1 provided to the resin composition RC in the first curing may be less than the amount of the second light UV-2 provided in the second curing. The first curing may include providing the first light UV-1 to the resin composition RC to pre-cure the resin composition RC. In embodiments, the pre-curing means partially progressing the polymerization reaction of the resin composition RC to a level where the resin composition RC is not completely cured. The pre-curing is distinguished from curing in the second curing, and a different amount of light may be irradiated from the amount of light provided in the second curing. For example, the pre-curing may include irradiating the resin composition RC with a light amount of about ⅓ to about 1/10 of the amount of light required or utilized in the second curing, but an embodiment of the present disclosure is not limited thereto. The resin composition RC may be pre-cured in the first curing and formed into a preliminary adhesive member P-AP (FIG. 12C).

In FIG. 12B, the first light UV-1 is illustrated as being directly irradiated to the resin composition RC, but an embodiment of the present disclosure is not limited thereto. On top of the resin composition RC applied to the first plate BP1, a carrier film that transmits ultraviolet light may be placed apart from the first plate BP1 on which the resin composition RC is applied. In embodiments, the first light UV-1 may be irradiated to the top of the carrier film and may be provided to the resin composition RC by transmitting the carrier film.

Referring to FIG. 12C, the method of manufacturing a display device according to an embodiment may include a second curing including providing a second light UV-2 to the preliminary adhesive member P-AP. The second curing may include laminating a second plate BP2 on the preliminary adhesive member P-AP, and then irradiating the preliminary adhesive member P-AP with the second light UV-2 to cure the preliminary adhesive member P-AP. The second light UV-2 may be provided from above the second plate BP2 and may be provided to the preliminary adhesive member P-AP by transmitting through the second plate BP2. The second light UV-2 may be ultraviolet light. The preliminary adhesive member P-AP may be completely cured by the second light UV-2, and the preliminary adhesive member P-AP may be completely cured to form the adhesive member AP as illustrated in FIG. 12D. During the process of the preliminary adhesive member P-AP being completely cured, the first plate BP1 and the second plate BP2 may be combined. The first plate BP1 and the second plate BP2 may be combined with each other through the adhesive member AP.

The second plate BP2 may be the display module DM or a window WP described in FIG. 8. The second plate BP2 may be different from the first plate BP1. For example, if the first plate BP1 is the display module DM, the second plate BP2 may be the window WP. In embodiments, if the first plate BP1 is the window WP, the second plate BP2 may be the display module DM.

As described with reference to FIGS. 12A to 12D, the adhesive member AP of an embodiment may be formed by providing light to the resin composition RC at least twice through the first curing and the second curing, but an embodiment of the present disclosure is not limited thereto. For example, the adhesive member AP may be formed without a pre-curing step by providing light to the resin composition RC once, or may be formed by providing light to the resin composition RC three or more times.

If (e.g., when) the resin composition RC of an embodiment is completely cured by ultraviolet light, an elastic modulus at about 25° C. may be about 0.01 MPa or more and about 0.1 MPa or less. For example, the cured product of the resin composition RC may have an elastic modulus of about 0.01 MPa or more and about 0.1 MPa or less at a temperature of about 25° C. In embodiments of the present specification, the “cured product” may mean everything formed by completely curing the resin composition RC and, for example, may mean an adhesive member AP.

In embodiments, the adhesive member AP, which is a cured product of the resin composition RC, may have a 180° peel strength of about 500 gf/25 mm or more for at least one selected from among a polymer substrate and a glass substrate at a temperature of about 25° C. For example, the cured product of the resin composition RC may have a 180° peel strength of about 500 gf/25 mm or more and about 1000 gf/25 mm or less for at least one selected from among a glass substrate and a polymer substrate at a temperature of about 25° C. The resin composition RC of an embodiment contains 2-acryloyloxyethyl succinate and 4-hydroxybutyl acrylate in set amount ranges, thereby satisfying the above-described viscosity range, and after curing, satisfying the above-described storage elastic modulus and 180° peel strength. Therefore, the adhesive member AP formed from the resin composition RC of an embodiment may exhibit excellent adhesiveness and flexibility.

FIGS. 13A to 13E are diagrams illustrating the method of manufacturing a display device according to an embodiment. FIGS. 13A to 13E are diagrams illustrating providing a resin composition in the method of manufacturing a display device according to an embodiment. In the method of manufacturing a display device according to an embodiment described with reference to FIGS. 13A to 13E, any content overlapping with that described in FIGS. 3 to 12D may not be described again, and differences will be mainly described.

FIG. 13A is a diagram schematically illustrating providing a resin composition RC on a first plate BP1 in a method of manufacturing a display device according to an embodiment. FIG. 13B is a diagram schematically illustrating the first plate BP1 on a plane.

Referring to FIGS. 13A and 13B, the resin composition RC of an embodiment may be provided on a first area AA1 and a second area AA2 of the first plate BP1 according to a preset application amount. The resin composition RC may be provided on the first plate BP1 by an inkjet printing method. The first area AA1 and the second area AA2 may be defined on the first plate BP1. The first area AA1 and the second area AA2 may be areas set or arbitrarily set on the first plate BP1. The first area AA1 may correspond to a central portion of the first plate BP1. The second area AA2 may correspond to an edge portion of the first plate BP1 relative to the first area AA1. On a plane defined by the first direction DR1 and the second direction DR2, the second area AA2 may be around (e.g., surround) the first area AA1. In an embodiment, the first width W1 in the first direction DR1 and the second width W2 in the second direction DR2 of the second area AA2 may each be about 3 mm or less, but an embodiment of the present disclosure is not limited thereto.

The planar area of the first area AA1 may be relatively larger than the planar area of the second area AA2. According to an embodiment, the first area AA1 of the first plate BP1 may correspond to at least a portion of the display area DA of the display device DD (FIG. 9). In embodiments, the second area AA2 of the first plate BP1 may correspond to at least a portion of the non-display area NDA of the display device DD (FIG. 9).

The first area AA1 may include a plurality of first unit areas AA1-1. The second area AA2 may include a plurality of second unit areas AA2-1 and a plurality of third unit areas AA2-2. On a plane, each of the first to third unit areas AA1-1, AA2-1, and AA2-2 may have the same area, but an embodiment of the present disclosure is not limited thereto. In the first plate BP1 of an embodiment, if (e.g., when) the planar areas of each of the first to third unit areas AA1-1, AA2-1, and AA2-2 are the same, the number of the first unit areas AA1-1 included in the first area AA1 may be greater than the number of the second and third unit areas AA2-1, and AA2-2 included in the second area AA2.

Each of the second unit areas AA2-1 and the third unit areas AA2-2 may be provided at an edge of the first plate BP1 and may have a shape around (e.g., surrounding) the first area AA1 on a plane. The third unit areas AA2-2 may be provided closer to the first area AA1 than the second unit areas AA2-1. For example, the third unit areas AA2-2 may directly contact the first area AA1 and may have a closed-line shape around (e.g., surrounding) the first area AA1 on a plane. The second unit areas AA2-1 may be spaced apart from the first area AA1 and may have a closed-line shape around (e.g., surrounding) the first area AA1 with the third unit areas AA2-2 interposed therebetween.

In an embodiment, the resin composition RC may be provided in different amounts on the first area AA1 and the second area AA2 of the first plate BP1. For example, because the first area AA1 of the first plate BP1 may have a larger planar area than the second area AA2, the resin composition RC may be provided in a larger amount on the first area AA1 of the first plate BP1 than on the second area AA2. The amounts of the resin composition RC provided on the first area AA1 and the second area AA2 may be adjusted by controlling the discharge amount of the resin composition RC discharged from the nozzles NZ of the inkjet head IHD. For example, the discharge amount of the resin composition RC discharged from the nozzle NZ on the first area AA1 may be greater than the discharge amount of the resin composition RC discharged from the nozzle NZ on the second area AA2. Without being limited thereto, a greater number of nozzles NZ may be on the first area AA1 than on the second area AA2.

In some embodiments, if (e.g., when) the same planar area is used as a standard, the amount of the resin composition RC applied to the first area AA1 may be different from the amount of the resin composition RC applied to the second area AA2. For example, if (e.g., when) each of the first to third unit areas AA1-1, AA2-1, and AA2-2 has the same planar area, the amount of the resin composition RC applied to each of the first unit areas AA1-1 may be less or more than the amount of the resin composition RC applied to each of the second and third unit areas AA2-1 and AA2-2, but an embodiment of the present disclosure is not limited thereto. The amount of the resin composition RC applied to each of the first unit areas AA1-1 may be smaller than the amount of the resin composition RC applied to each of the second unit areas AA2-1.

In an embodiment, the resin composition RC may be applied on the first area AA1 in a constant (e.g., substantially constant) amount. For example, the amount of the resin composition RC discharged from the nozzles NZ and provided to each of the first unit areas AA1-1 may be substantially the same. In the present specification, substantially the same includes embodiments where the physical values are the same and embodiments where there is a difference within the range of process error. The resin composition RC may be applied to the first area AA1 in a constant thickness. Accordingly, the preliminary adhesive member P-AP (FIG. 13D) overlapping the first area AA1 may have a constant (e.g., substantially constant) thickness.

As described above, the resin composition RC of an embodiment may have viscosity characteristics that enable application in any suitable shape using an inkjet printing method. The amount of the resin composition RC applied to the second area AA2 may be set to be applied in different amounts depending on the location. In an embodiment, the amount of the resin composition RC applied to the second unit areas AA2-1 and the amount of the resin composition RC applied to the third unit areas AA2-2 may be respectively set. For example, the amount of the resin composition RC applied to the second unit areas AA2-1 and the amount of the resin composition RC applied to the third unit areas AA2-2 may be different from each other. The amount of the resin composition RC applied to the second unit areas AA2-1 spaced apart from the first area AA1 may be greater than that to the third unit areas AA2-2 adjacent to the first area AA1. The amount of the resin composition RC applied to the third unit areas AA2-2 may be smaller than the amount of the resin composition RC applied to the second unit areas AA2-1. However, an embodiment of the present disclosure is not limited thereto.

The resin composition RC of an embodiment may be applied on the second area AA2 of the first plate BP1 with a thickness having a height difference in the third direction DR3. The thickness of the resin composition RC may have a height difference including a highest point and a lowest point in the second area AA2. The resin composition RC applied on the second area AA2 may have a thickness including a highest point in the second unit area AA2-1 and a thickness including a lowest point in the third unit area AA2-2. However, an embodiment of the present disclosure is not limited thereto. In an embodiment, the thickness of the resin composition RC applied on the first area AA1 may be lower than the maximum thickness of the resin composition RC applied on the second area AA2. The thickness of the resin composition RC applied on the first area AA1 may be higher or lower than the minimum thickness of the resin composition RC applied on the second area AA2, and may be the same, and is not limited to any one embodiment.

FIG. 13C is a diagram illustrating curing a resin composition in a method of manufacturing a display device according to an embodiment. FIG. 13D is a diagram showing secondarily applying the resin composition RC in forming an adhesive member in a method of manufacturing a display device according to an embodiment.

Referring to FIG. 13C, the method of manufacturing a display device according to an embodiment may include applying the resin composition RC to the first area AA1 and the second area AA2 of the first plate BP1 and then curing the resin composition RC. The resin composition RC may be cured by light. For example, the resin composition RC may be exposed to a third light UV-1a. The third light UV-1a may be directly irradiated onto the resin composition RC applied on the first plate BP1. The third light UV-1a may be ultraviolet light, but is not limited thereto.

In an embodiment, a preliminary adhesive member P-AP (see FIG. 13D) may be formed from the resin composition RC cured by the third light UV-1a. For example, the resin composition RC may be at least partially polymerized and cured by the provided third light UV-1a to be formed into a preliminary adhesive member P-AP (see FIG. 13D). The resin composition RC cured by the third light UV-1a may have a constant (e.g., substantially constant) thickness in the first area AA1 and a thickness having a height difference in the second area AA2. In embodiments, the cured resin composition RC may have a thickness including a peak in the second unit area AA2-1 of the second area AA2. The resin composition RC applied to the first plate BP1 may have a maximum thickness in the second unit area AA2-1. The preliminary adhesive member P-AP (see FIG. 13D) having a height difference in the second area AA2 may be referred to as a “first preliminary adhesive member.”

The amount of light of the third light UV-1a irradiated to the resin composition RC in the curing the resin composition RC may be a level for pre-curing the resin composition RC. The unreacted resin composition RC may be further reacted to form a final adhesive member AP (FIG. 12D) from the preliminary adhesive member P-AP. An embodiment of the present disclosure is not limited thereto, and the amount of light of the third light UV-1a irradiated to the resin composition RC in the curing the resin composition RC may be a level for completely curing the resin composition RC.

The preliminary adhesive member P-AP formed from the resin composition RC may have different thicknesses in the first area AA1 and the second area AA2. For example, the preliminary adhesive member P-AP may have different maximum thicknesses in the first area AA1 and the second area AA2. Based on the same planar area, a first application amount of the resin composition RC provided in the first area AA1 may be smaller than a second application amount of the resin composition RC provided in the second area AA2. Accordingly, the average thickness of the preliminary adhesive member P-AP overlapping the first area AA1 may be smaller than the average thickness of the preliminary adhesive member P-AP overlapping the second area AA2.

If (e.g., when) the preliminary adhesive member P-AP overlapping the first area AA1 is referred to as a first preliminary adhesive portion, and the preliminary adhesive member P-AP overlapping the second area AA2 is referred to as a second preliminary adhesive portion, the thickness deviation of the second preliminary adhesive portion may be greater than the thickness deviation of the first preliminary adhesive portion. The first area AA1 may be divided into a plurality of first unit areas AA1-1 (FIG. 13B), and the resin composition may be applied in an equally set application amount to each of the plurality of first unit areas AA1-1. The second area AA2 may be divided into a plurality of second and third unit areas AA2-1 and AA2-2, and the resin composition RC may be applied in a preset application amount to each of the plurality of second and third unit areas AA2-1 and AA2-2. Because the coating amount of at least one selected from the plurality of second and third unit areas AA2-1 and AA2-2 is different from the coating amounts of the other unit areas AA2-1 and AA2-2, the weight deviation of the provided resin composition RC may occur. Accordingly, the thickness deviation of the second area AA2 may be relatively larger than the thickness deviation of the first area AA1.

The method of manufacturing a display device of an embodiment may further include additionally providing the resin composition RC on the first plate BP1. In an embodiment, the method of manufacturing a display device may further include secondarily applying the resin composition RC to the preliminary adhesive member P-AP.

Referring to FIG. 13D, the resin composition RC of an embodiment may be additionally provided on the first plate BP1 by an inkjet printing method. The resin composition RC may be provided to the preliminary adhesive member P-AP so as to overlap the second area AA2 of the first plate BP1. In the secondarily applying the resin composition RC, the resin composition RC may also be provided to the first area AA1.

In the secondarily applying the resin composition RC, the amount of the resin composition RC applied may be suitably or appropriately set in consideration of the thickness of the preliminary adhesive member P-AP. In an embodiment, the amount of the resin composition RC applied in the second application may be smaller than the first and second application amounts of the resin composition RC applied to the first area AA1 and the second area AA2 described above. For example, if (e.g., when) the amount of the resin composition RC applied to the first and second areas AA1 and AA2 is 100, the amount of the resin composition RC applied to the first and second areas AA1 and AA2 in the second application may be smaller than 100. The preliminary adhesive member P-AP having thickness deviation in a portion overlapping the second area AA2 may have thickness deviation reduced by the second application of the resin composition RC.

FIG. 13E is a diagram showing curing a resin composition in a method of manufacturing a display device according to an embodiment. Referring to FIGS. 13D and 13E together, after the secondarily coating the resin composition RC, secondarily curing the resin composition RC may be performed.

In an embodiment, fourth light UV-1b may be irradiated onto the resin composition RC provided on the first plate BP1. The fourth light UV-1b may be ultraviolet light but is not limited thereto. The fourth light UV-1b may be irradiated onto the resin composition RC to cure the resin composition RC. The resin composition RC may be polymerized and then cured by the fourth light UV-1b and may be formed into an adhesive member AP (FIG. 12D) together with the preliminary adhesive member P-AP. In FIG. 13E, the fourth light UV-1b is irradiated to both the first area AA1 and the second area AA2 as an illustration but is not limited thereto, and the fourth light UV-1b may be selectively irradiated only to the second area AA2 depending on the degree of curing of the preliminary adhesive member P-AP.

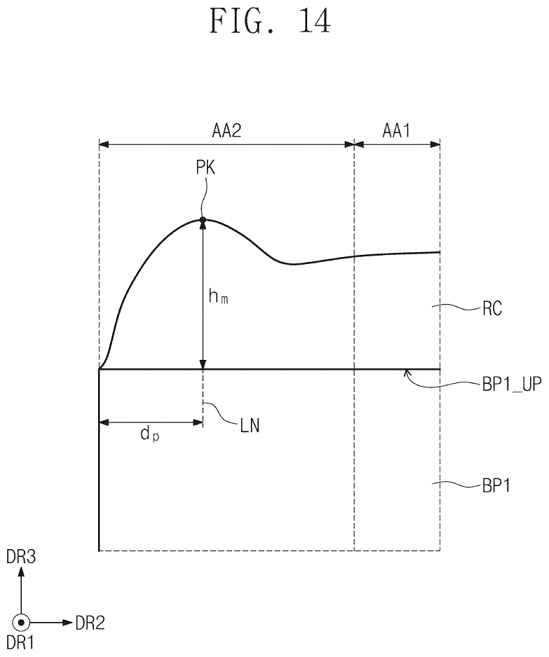

FIG. 14 is a cross-sectional view showing area AA′ in 13C in an enlarged manner. FIG. 14 is a diagram illustrating the shape of the resin composition RC applied on the first plate BP1.

The resin composition RC applied on the first plate BP1 may include a first portion overlapping the first area AA1 and a second portion overlapping the second area AA2. The resin composition RC may be applied to the first area AA1 of the first plate BP1 with a constant (e.g., substantially constant) thickness. As a result, the resin composition RC may have a flat upper surface in the first portion overlapping the first area AA1.

The resin composition RC may be applied to the second area AA2 of the first plate BP1 with a thickness having a height difference including the highest point and the lowest point. As a result, the resin composition RC may have a peak part PK having a maximum thickness in the third direction DR3 in the second portion. The peak part PK overlaps the second area AA2 and may refer to a point where the thickness of the resin composition RC applied from the upper surface BP1_UF of the first plate BP1 is maximum. The resin composition RC applied to the second area AA2 may include a peak part PK having a maximum height hm in the second portion overlapping the second area AA2.

The thickness of the resin composition RC in the second portion may gradually decrease in a direction away from the first area AA1. For example, the thickness of the resin composition RC applied to the second area AA2 of the first plate BP1 may gradually decrease from the peak part PK to the edge. In embodiments of this specification, the edge refers to the end point where the resin composition RC is applied to the first plate BP1. In embodiments, in this specification, a portion in the second portion where the thickness decreases from the peak part PK to the edge may be referred to as a slope.

In an embodiment, the horizontal distance dₚ from the edge of the resin composition RC applied to the second area AA2 to the peak part PK may be about 500 μm or less. For example, the horizontal distance dₚ from the edge of the first plate BP1 on which the resin composition RC is applied to the peak part PK may be about 300 μm or more and about 500 μm or less. The horizontal distance dₚ from the edge to the peak part PK may mean the shortest distance measured between a first imaginary line LN extended in the third direction DR3 from the peak part PK and the edge of the adhesive member AP. If the horizontal distance dₚ from the edge of the resin composition RC applied to the second area AA2 to the peak part PK increases, a slope may be recognized from the outside of the display devices DD, DD-a and DD-b (see FIGS. 3, 5 and 7), which may deteriorate image quality.

The resin composition of an embodiment has a suitable or appropriate viscosity range that may be applied in an intended shape through an inkjet printing method by including the composition described above and may provide an effect of reducing the horizontal distance dₚ from an edge to a peak part PK to a set or certain range. In embodiments, the adhesive member formed from the resin composition of an embodiment has a storage elastic modulus of about 0.01 MPa or more and about 0.1 MPa or less at about 25° C., and thus may exhibit excellent adhesive reliability and elastic modulus.

Hereinafter, with reference to examples and comparative examples, an adhesive member according to an embodiment of the present disclosure and a display device according to an embodiment will be described in more detail. The examples shown below are examples to help understanding of the subject matter of the present disclosure, and the scope of the present disclosure is not limited thereto.

### Examples

### 1. Preparation of Resin Compositions

The resin compositions of the Examples and Comparative Examples were prepared by the mixing ratios described in Tables 1 and 2. The materials disclosed in Tables 1 and 2 were provided in a light shielding poly container at respective weight ratios. In addition, Omnirad 819 (IGM Resin) as a photoinitiator was provided at about 2 wt % based on the total weight of the resin composition. Thereafter, the compositions were stirred at about 100 rpm at room temperature for about 1 hour using a Three-One Motor (product of Shinto Scientific Co., Ltd.) as a stirrer so as to uniformly mix, thereby preparing resin compositions of the Examples and Comparative Examples.

TABLE 1

| | Example 1 | Example 2 | Example 3 | Example 4 |
|---|---|---|---|---|
| UF-C051 | 3.00% | 3.00% | 3.00% | 3.00% |
| UF-C052 | 3.00% | 3.00% | 3.00% | 3.00% |
| UN6304 | 6.00% | 6.00% | 6.00% | 6.00% |
| HOA-MS | 7.00% | 6.00% | 9.00% | 5.00% |
| HOA-MPE | — | — | — | — |
| DEAA | — | — | — | — |
| 4-HBA | 7.00% | 7.00% | 7.00% | 10.00% |
| 2-EHA | 49.00% | 58.00% | 47.00% | 58.00% |
| THF-A | 14.00% | 6.00% | 16.00% | 5.00% |
| EHDG-AT | 11.00% | 11.00% | 9.00% | 10.00% |

TABLE 2

| | Comparative | Comparative | Comparative | Comparative | Comparative | Comparative | Comparative |
|---|---|---|---|---|---|---|---|
| | Example 1 | Example 2 | Example 3 | Example 4 | Example 5 | Example 6 | Example 7 |
| UF-C051 | 15.50% | 3.00% | 3.00% | 3.00% | 3.00% | 3.0% | 3.0% |
| UF-C052 | | 3.00% | 3.00% | 3.00% | 3.00% | 3.0% | 3.0% |
| UN6304 | — | 6.00% | 6.00% | 6.00% | 7.00% | 6.0% | 7.0% |
| HOA-MS | — | — | — | 9.00% | — | 11.0% | 6.0% |
| HOA-MPE | — | — | 7.00% | — | — | — | — |
| DEAA | — | — | — | — | 65.00% | — | — |
| 4-HBA | 22.10% | 7.00% | 7.00% | — | 7.00% | 7.0% | 4.0% |
| 2-EHA | 62.40% | 55.00% | 49.00% | 47.00% | — | 45.0% | 52.0% |
| THF-A | — | 15.00% | 14.00% | 18.00% | 10.00% | 14.0% | 15.0% |
| EHDG-AT | — | 11.00% | 11.00% | 14.00% | 5.00% | 11.0% | 10.0% |

### <Components Included in the Resin Compositions in Table 1 and Table 2>

UF-C051: urethane acrylate (product of Kyoeisha Kagaku Co. Ltd., weight average molecular weight: 35000)
UF-C052: urethane acrylate (product of Kyoeisha Kagaku Co. Ltd., weight average molecular weight: 10000)
UN6304: urethane acrylate (product of Negami Chemical Industrial Co., Ltd., weight average molecular weight: 10000)
HOA-MS: 2-acryloyloxyethyl succinate
HOA-MPE: 2-acryloyloxy ethyl-2-hydroxy-ethylphthalic acid
DEAA: N,N-diethylacrylamide (KJ Chemicals Co., Ltd.)
4-HBA: 4-hydroxybutyl acrylate (product of Osaka Organic Chemical Industry Ltd.)
2-EHA: 2-ethylhexyl acrylate (product of TOAGOSEI Co., Ltd.)
THF-A: tetrahydrofurfuryl acrylate (product of KYOEISHA CHEMICAL Co., Ltd.)
EHDG-AT: 2-ethylhexyl diglycol acrylate (product of KYOEISHA CHEMICAL Co., Ltd.)

### 2. Evaluation of Resin Compositions and Adhesive Members

### 1) Measurement of Viscosity of Resin Compositions

The shear viscosity of the resin compositions of the Examples and Comparative Examples was measured at a temperature of about 25° C. by a JIS Z8803 method. The shear viscosity of the resin composition was measured using a viscometer TVE-25L (TOKI SANGYO Co. Ltd.) at a speed condition of about 10 rpm, and the results are shown in Tables 3 and 4.

### 2) Measurement of Storage Elastic Modulus of Adhesive Members

On a glass substrate (product of Matsunami Glass, S1112), a release-treated PET film (NP100A, product of Panac Co. Ltd.) and a silicone rubber sheet (product of Tigers Polymer Co. Ltd.) having a hole of about 8 mm in diameter were sequentially laminated. About 28 μL of each of the resin compositions of the Examples and Comparative Examples was provided in the silicone rubber hole. After that, light was irradiated using UV LED lamps having peak wavelengths of about 405 nm and about 365 nm so that the total amounts of light were about 220 mJ/cm² and about 380 mJ/cm², respectively. After that, light was irradiated using a UV LED lamp having a peak wavelength of about 395 nm so that the total amount of light was about 4000 mJ/cm² on the upper part of the glass substrate, thereby curing the resin composition and obtaining a circular sample having a diameter of about 8 mm and a thickness of about 500 μm.

The obtained sample was subjected to dynamic viscoelasticity measurement. Storage elastic modulus was measured at a measurement temperature of about from −50° C. to 60° C. and a measurement frequency of about 1 Hz according to JIS K7244-7 using MCR302 (product of Anton-Paar). The storage elastic modulus at about 25° C. confirmed through measurement was confirmed, and the results are shown in Tables 3 and 4.

### 3) Measurement of 180° Peel Strength of Adhesive Members

Each of the resin compositions of the Examples and Comparative Examples was applied to a thickness of about 50 μm on a soda-lime glass (product of Central Glass Co., Ltd.) of about 26 mm×76 mm using a bar coater. Light was irradiated onto the soda-lime glass to which the resin composition was applied using UV LED lamps having peak wavelengths of about 365 nm and about 395 nm so that the total amounts of light were about 800 mJ/cm² and about 400 mJ/cm², respectively. A PET film (A4360, product of TOYOBO Co., Ltd.) having a size of about 20 mm×150 mm was provided on the resin composition to which the light had been irradiated and bonded at a bonding pressure of about 0.15 MPa. After bonding, a sample was obtained by irradiating light to the PET film using a UV LED lamp having a peak wavelength of about 395 nm so that the total amount of light was about 4000 mJ/cm².

The obtained sample was measured for the peeling strength using a universal testing machine (product of Instron Corporation, type 5965) at a constant temperature environment of about 25° C. and about 60° C., at a speed of about 300 mm/min with a peeling angle of about 180°. The average value of about 50 mm of peeling was obtained, and the results of evaluating the obtained value by multiplying by 1.25 are shown in Tables 3 and 4.

### 4) Evaluation of Coating Shape of Resin Compositions

A DevicePrinter-CX (Microjet Co., Ltd.) equipped with a KM1024i (Konica Minolta Co., Ltd.) was used as an inkjet device. The voltage, pulse driving cycle, and temperature were adjusted as discharge conditions so that the discharge speed was about 5.5 m/s or more and about 6.5 m/s or less. After setting the coating conditions so that the shape of about 55 mm×120 mm and the preset coating amount were satisfied, the composition was applied to a PET film (product of SK Chemicals, SH 86) that had been washed using an atmospheric plasma treatment device. The shape of a coated film of each of the resin compositions of the Examples and Comparative Examples applied to the end of the PET film was measured using a Keyence laser microscope VK-X3000. The horizontal distance from the edge to the peak part of the resin composition applied to the PET film was measured and is shown in Tables 3 and 4 below. The first decimal place of the result obtained from the horizontal distance measurement was rounded up and measured as an “edge to peak distance.” Meanwhile, Comparative Examples 1 and 6 had high viscosity, so the peel strength and “edge to peak distance” evaluation was not performed. In addition, the adhesive members manufactured from the resin compositions of Comparative Examples 3 to 5 and 7 were confirmed to have insufficient peel strength, so the “edge to peak distance” evaluation was not performed.

TABLE 3

| | Example 1 | Example 2 | Example 3 | Example 4 |
|---|---|---|---|---|
| Viscosity/mPa · s | 22 | 19 | 21 | 17 |
| Elastic modulus/MPa | 0.09 | 0.06 | 0.1 | 0.07 |
| Peel strength | 1000 | 700 | 700 | 1000 |
| (gf/25 mm) | | | | |
| Edge to peak | 410 μm | 380 μm | 360 μm | 470 μm |
| distance | | | | |

TABLE 4

| | Comparative | Comparative | Comparative | Comparative | Comparative | Comparative | Comparative |
|---|---|---|---|---|---|---|---|
| | Example 1 | Example 2 | Example 3 | Example 4 | Example 5 | Example 6 | Example 7 |
| Viscosity/ | 32 | 13 | 21 | 17 | 16 | 29 | 17 |
| mPa · s | | | | | | | |
| Elastic | 0.05 | 0.03 | 0.05 | 0.06 | 0.61 | 0.1 | 0.06 |
| modulus/ | | | | | | | |
| MPa | | | | | | | |
| Peel | — | 1000 | 200 | 300 | 80 | — | 300 |
| strength | | | | | | | |
| (gf/25 mm) | | | | | | | |
| Edge to | — | 580 μm | — | — | — | — | — |
| peak | | | | | | | |
| distance | | | | | | | |

Referring to Table 3 and Table 4, it can be confirmed that all the resin compositions of Examples 1 to 4, each containing 2-acryloyloxyethyl succinate and 4-hydroxybutyl acrylate in specific amount ranges, had a viscosity appropriate for application via inkjet printing.

In comparison, it can be confirmed that the resin composition of Comparative Example 1, which does not contain 2-acryloyloxyethyl succinate and contains an excessive amount of 4-hydroxybutyl acrylate, had an excessively high viscosity. In the case of Comparative Example 2, because 2-acryloyloxyethyl succinate is not contained, the viscosity of the resin composition was also somewhat low, and it can be confirmed that the “edge to peak distance” exceeded about 500 μm.

In addition, Comparative Example 3, which contains HOA-MPE instead of 2-acryloyloxyethyl succinate compared to Example 1, exhibited a similar viscosity level, but the peel strength of the adhesive member manufactured from the resin composition was significantly reduced. In Comparative Example 4, which does not include 4-hydroxybutyl acrylate, and Comparative Example 5, which does not include 2-acryloyloxyethyl succinate, the peel strength was significantly reduced compared to the Examples. In addition, the resin composition of Comparative Example 6 showed high viscosity because the content of 2-acryloyloxyethyl succinate exceeded about 10 wt %, and in Comparative Example 7, the content of 4-hydroxybutyl acrylate was less than about 5 wt %, so it was confirmed that the peel strength was reduced if (e.g., when) manufactured as an adhesive member.

The resin composition of an embodiment may include set or specific components in set or specific content ranges and exhibit a suitable or appropriate viscosity range that may be applied in an intended shape through an inkjet printing method.

The method of manufacturing a display device of an embodiment may suitably or appropriately control the film thickness distribution near the edge of a target substrate by using the resin composition of an embodiment if (e.g., when) forming an adhesive member, thereby enabling bonding without any unbonded portion being visible.

The display device and electronic device of an embodiment may exhibit excellent adhesiveness and elasticity by including the adhesive member of an embodiment.

In the above, description has been made with reference to embodiments of the present disclosure, but those skilled or of ordinary skill in the art may understand that various suitable modifications and changes may be made to the present disclosure insofar as such modifications and changes do not depart from the spirit and technical scope of the present disclosure set forth in the appended claims and equivalents thereof.

Therefore, the technical scope of the present disclosure is not to be limited to the contents stated in the detailed description of the specification but should be determined by the appended claims and equivalents thereof.

What is claimed is:

1. A resin composition comprising at least one (meth)acrylate monomer, at least one urethane acrylate oligomer, and at least one photoinitiator,
wherein the resin composition comprises, based on a total weight of the resin composition:
about 5 wt % or more and about 10 wt % or less of 2-acryloyloxyethyl succinate; and
about 5 wt % or more and about 10 wt % or less of 4-hydroxybutyl acrylate.

2. The resin composition of claim 1,
wherein a viscosity of the resin composition at about 25° C. is about 15 mPa·s or more and about 25 mPa·s or less.

3. The resin composition of claim 1, wherein the urethane acrylate oligomer has a weight average molecular weight of about 10,000 or more and about 38,000 or less.

4. The resin composition of claim 1, further comprising one or more kinds of the (meth)acrylate monomers different from the 4-hydroxybutyl acrylate.

5. The resin composition of claim 4, further comprising at least one selected from among 2-ethylhexyl acrylate, tetrahydrofurfuryl acrylate, and 2-ethylhexyl diglycol acrylate.

6. The resin composition of claim 1, wherein a storage elastic modulus at about 25° C. after photocuring the resin composition is about 0.01 MPa or more and about 0.1 MPa or less.

7. A method of manufacturing a display device, the method comprising:
providing a resin composition on a first plate; and
forming an adhesive member from the resin composition,
wherein the resin composition comprises:
at least one (meth)acrylate monomer, at least one urethane acrylate oligomer, and at least one photoinitiator,
based on a total weight of the resin composition,
about 5 wt % or more and about 10 wt % or less of 2-acryloyloxyethyl succinate; and
about 5 wt % or more and about 10 wt % or less of 4-hydroxybutyl acrylate.

8. The method of manufacturing a display device of claim 7,
wherein a first area and a second area around the first area is defined in the first plate,
in the providing of the resin composition,
the resin composition is provided in the first area with a constant thickness and in the second area with a height difference in a thickness direction.

9. The method of manufacturing a display device of claim 8, wherein a thickness of the resin composition applied to the first area is smaller than a maximum thickness of the resin composition applied to the second area.

10. The method of manufacturing a display device of claim 8, wherein the resin composition applied to the second area comprises a peak part having a maximum thickness from an upper surface of the first plate.

11. The method of manufacturing a display device of claim 10, wherein a horizontal distance from an edge of the first plate to which the resin composition is applied to the peak part is about 300 μm or more and about 500 μm or less.

12. The method of manufacturing a display device of claim 7, wherein a viscosity of the resin composition at about 25° C. is about 15 mPa·s or more and about 25 mPa·s or less.

13. The method of manufacturing a display device of claim 12, wherein the resin composition is provided by an inkjet printing method.

14. An electronic device comprising:
a display device; and
a control part to control the display device,
wherein the display device comprising:
a display panel;
a window on the display panel; and
an adhesive member comprising a polymer derived from a resin composition comprising at least one (meth)acrylate monomer, at least one urethane acrylate oligomer, and at least one photoinitiator, wherein the resin composition comprises, based on a total weight of the resin composition, about 5 wt % or more and about 10 wt % or less of 2-acryloyloxyethyl succinate and about 5 wt % or more and about 10 wt % or less of 4-hydroxybutyl acrylate, the adhesive member being between the display panel and the window.

15. The electronic device of claim 14, wherein the adhesive member has a storage elastic modulus at about 25° C. of about 0.01 MPa or more and about 0.1 MPa or less.

16. The electronic device of claim 14, wherein the adhesive member has a 180° peel strength of about 500 gf/25 mm or more for at least one selected from among a glass substrate and a polymer substrate at a temperature of about 25° C.

17. The electronic device of claim 14, wherein the urethane acrylate oligomer has a weight average molecular weight of about 10,000 or more and about 38,000 or less.

18. The electronic device of claim 14, wherein the resin composition further comprises one or more kinds of the (meth)acrylate monomers different from the 4-hydroxybutyl acrylate.

19. The electronic device of claim 14, wherein the resin composition further comprising at least one selected from among 2-ethylhexyl acrylate, tetrahydrofurfuryl acrylate, and 2-ethylhexyl diglycol acrylate.

20. The electronic device of claim 14, wherein the electronic device is a television, a monitor, an outdoor billboard, a personal computer, a laptop computer, a personal digital assistant, a vehicle display device, a game console, a smartwatch, or a camera.
